(19) United States
(12) Patent Application Publication
(10) Pub. No.: US 2026/0107454 A1
(43) Pub. Date: Apr. 16, 2026

(54) THREE-DIMENSIONAL SEMICONDUCTOR DEVICE AND METHOD OF FABRICATING THE SAME

(71) Applicant: Samsung Electronics Co., Ltd., Suwon-si (KR)

(72) Inventors: Youngsik LEE, Suwon-si (KR); Gwang-Hyun BAEK, Suwon-si (KR); Jungeun SHIN, Suwon-si (KR); Hyeonah YANG, Suwon-si (KR); Jinkwan LEE, Suwon-si (KR); Je-Woo HAN, Suwon-si (KR)

(73) Assignee: Samsung Electronics Co., Ltd., Suwon-si (KR)

(21) Appl. No.: 19/257,062

(22) Filed: Jul. 1, 2025

(30) Foreign Application Priority Data
Jul. 24, 2024 (KR) 10-2024-0098084

(51) Int. Cl. H10B 12/00; G11C 5/06; H10D 80/30; H10W 72/90

(52) U.S. Cl. CPC H10B 12/50; G11C 5/063; H10B 12/09; H10B 12/482; H10B 12/488; H10D 80/30; H10W 72/923

(57) ABSTRACT

A three-dimensional semiconductor device may include a first cell array structure, a peripheral circuit structure on the first cell array structure, and a second cell array structure spaced apart from the peripheral circuit structure with the first cell array structure therebetween. The first cell array structure may include a lower insulating layer adjacent to the second cell array structure. Each of the first and second cell array structures may include semiconductor patterns spaced apart from each other in a vertical direction and extending in a first direction, word lines respectively enclosing the semiconductor patterns and extending in a second direction, and a bit line on first side surfaces of the semiconductor patterns and extending in the vertical direction. The first and second directions may be parallel to a top surface of the lower insulating layer.

### CROSS-REFERENCE TO RELATED APPLICATIONS

This U.S. non-provisional patent application claims priority under 35 U.S.C. § 119 to Korean Patent Application No. 10-2024-0098084, filed on Jul. 24, 2024 in the Korean Intellectual Property Office, the entire contents of which are hereby incorporated by reference.

### BACKGROUND

The present disclosure relates to a three-dimensional semiconductor device and/or a method of fabricating the same, and more particularly, to a three-dimensional semiconductor device with higher reliability and/or higher integration and/or a method of fabricating the same.

Due to their small-size, multifunctional, and/or low-cost characteristics, semiconductor devices may be important elements in the electronics industry. Semiconductor devices may be classified as a semiconductor memory device for storing data, a semiconductor logic device for processing data, and a hybrid semiconductor device including both of memory and logic elements.

With the recent trend of higher speed and lower power consumption of electronic devices, semiconductor devices in electronic devices may be required to have higher operating speeds and/or lower operating voltages. It may be necessary to increase an integration density of the semiconductor device. However, as the integration density of the semiconductor device increases, the semiconductor device may suffer from deteriorated electrical characteristics and/or lower production yield. Accordingly, many studies are being conducted to improve the electrical characteristics and/or production yield of the semiconductor device.

### SUMMARY

An embodiment of inventive concepts provides a three-dimensional semiconductor device with an increased integration density.

An embodiment of inventive concepts provides a method of lowering a process difficulty and/or a fabrication cost in a process of fabricating a three-dimensional semiconductor device and a three-dimensional semiconductor device fabricated from the process of fabricating the three-dimensional semiconductor device.

According to an embodiment of inventive concepts, a three-dimensional semiconductor device may include a first cell array structure; a peripheral circuit structure on the first cell array structure; and a second cell array structure spaced apart from the peripheral circuit structure with the first cell array structure therebetween. The first cell array structure may include a lower insulating layer adjacent to the second cell array structure. Each of the first cell array structure and the second cell array structure may include semiconductor patterns spaced apart from each other in a vertical direction perpendicular to a top surface of the lower insulating layer and extending in a first direction parallel to the top surface of the lower insulating layer; word lines respectively enclosing the semiconductor patterns and extending in a second direction, which may be parallel to the top surface of the lower insulating layer and may not be parallel to the first direction; and a bit line on first side surfaces of the semiconductor patterns and extending in the vertical direction.

According to an embodiment of inventive concepts, a three-dimensional semiconductor device may include a first cell array structure; a peripheral circuit structure on the first cell array structure; and a second cell array structure spaced apart from the peripheral circuit structure with the first cell array structure therebetween. The first cell array structure may include a lower insulating layer, which may be adjacent to the second cell array structure, and lower bonding pads in the lower insulating layer. The second cell array structure may include cell bonding pads in contact with corresponding ones of the lower bonding pads. Each of the first cell array structure and the second cell array structure may include a bit line connection region and a word line connection region; semiconductor patterns on the bit line connection region, the semiconductor patterns being spaced apart from each other in a vertical direction and extending in a first direction, the vertical direction being perpendicular to a top surface of the lower insulating layer, and the first direction parallel to the top surface of the lower insulating layer; word lines respectively enclosing the semiconductor patterns and extending in a second direction to a region on the word line connection region, the second direction being parallel to the top surface of the lower insulating layer and not being parallel to the first direction; and a bit line on the bit line connection region and extending in the vertical direction, the bit line being on first side surfaces of the semiconductor patterns.

According to an embodiment of inventive concepts, a three-dimensional semiconductor device may include a first cell array structure; a peripheral circuit structure on the first cell array structure; and a second cell array structure spaced apart from the peripheral circuit structure with the first cell array structure therebetween. The peripheral circuit structure may include peripheral circuit transistors and peripheral bonding pads. The peripheral bonding pads may be connected to the peripheral circuit transistors. The first cell array structure may include upper bonding pads in contact with corresponding ones of the peripheral bonding pads. The first cell array structure may include a lower insulating layer adjacent to the second cell array structure. Each of the first cell array structure and the second cell array structures may include a bit line connection region and a word line connection region; semiconductor patterns on the bit line connection region, the semiconductor patterns being spaced apart from each other in a vertical direction and extending in a first direction, the vertical direction being perpendicular to a top surface of the lower insulating layer, and the first direction being parallel to the top surface of the lower insulating layer; word lines respectively enclosing the semiconductor patterns and extending in a second direction to a region on the word line connection region, the second direction being parallel to the top surface of the lower insulating layer and not being parallel to the first direction; and a bit line on the bit line connection region and extending in the vertical direction, the bit line being on first side surfaces of the semiconductor patterns.

### BRIEF DESCRIPTION OF THE DRAWINGS

FIG. 1 is a circuit diagram schematically illustrating a three-dimensional semiconductor device according to an embodiment of inventive concepts.

FIGS. 2A, 2B, and 2C are perspective views schematically illustrating a three-dimensional semiconductor device according to an embodiment of inventive concepts.

FIG. 3 is a sectional view illustrating a three-dimensional semiconductor device according to an embodiment of inventive concepts.

FIG. 4 is a plan view illustrating a three-dimensional semiconductor device according to an embodiment of inventive concepts.

FIG. 5A is a sectional view illustrating a three-dimensional semiconductor device according to an embodiment of inventive concepts and corresponding to a line A-A′ of FIG. 4.

FIG. 5B is a sectional view illustrating a three-dimensional semiconductor device according to an embodiment of inventive concepts and corresponding to a line B-B′ of FIG. 4.

FIGS. 6 to 12 are sectional views illustrating a method of fabricating a three-dimensional semiconductor device, according to an embodiment of inventive concepts.

FIGS. 13 to 17 are sectional views illustrating three-dimensional semiconductor devices according to some embodiments of inventive concepts.

### DETAILED DESCRIPTION

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

Example embodiments of inventive concepts will now be described more fully with reference to the accompanying drawings, in which some example embodiments are shown.

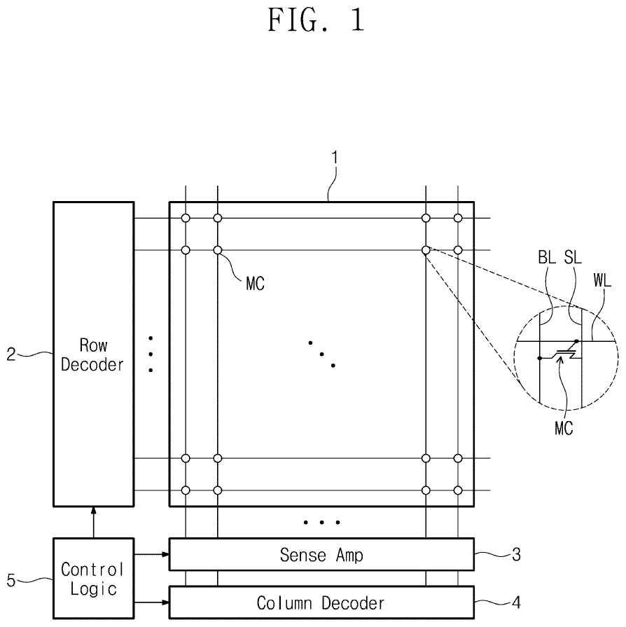

FIG. 1 is a circuit diagram schematically illustrating a three-dimensional semiconductor device according to an embodiment of inventive concepts.

Referring to FIG. 1, a three-dimensional semiconductor device may include a memory cell array 1, a row decoder 2, a sense amplifier 3, a column decoder 4, and a control logic 5.

The memory cell array 1 may include word lines WL, bit lines BL, source lines SL, and memory cells MC. The memory cells MC may be three-dimensionally arranged, and each of the memory cells MC may be connected to one of the word lines WL, one of the bit lines BL, and one of the source lines SL. In an embodiment, each of the memory cells MC may include one transistor including a memory layer or a data storing layer.

The row decoder 2 may be configured to decode address information, which is input from the outside, and to select one of the word lines WL of the memory cell array 1, based on the decoded address information. The address information decoded by the row decoder 2 may be provided to a row driver (not shown), and in this case, the row driver may provide respective voltages to the selected one of the word lines WL and the unselected ones of the word lines WL, in response to the control of a control circuit.

The sense amplifier 3 may be configured to sense, amplify, and output a difference in voltage between one of the bit lines BL, which is selected based on address information decoded by the column decoder 4, and a reference bit line.

The column decoder 4 may establish a data transmission path between the sense amplifier 3 and an external device (e.g., a memory controller). The column decoder 4 may be configured to decode address information, which is input from the outside, and to select one of the bit lines BL, based on the decoded address information.

The control logic 5 may be configured to generate control signals, which are used to control data-writing or data-reading operations on the memory cell array 1.

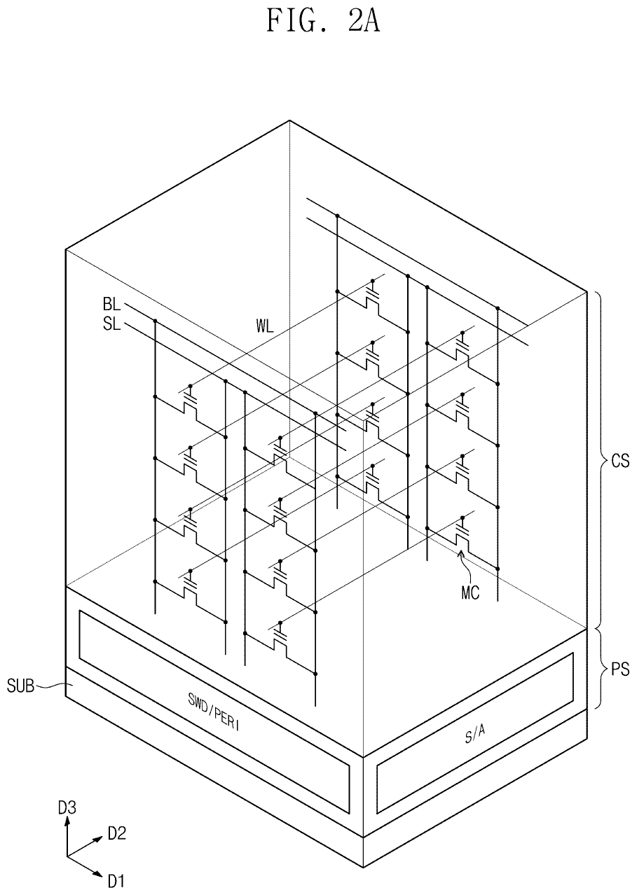

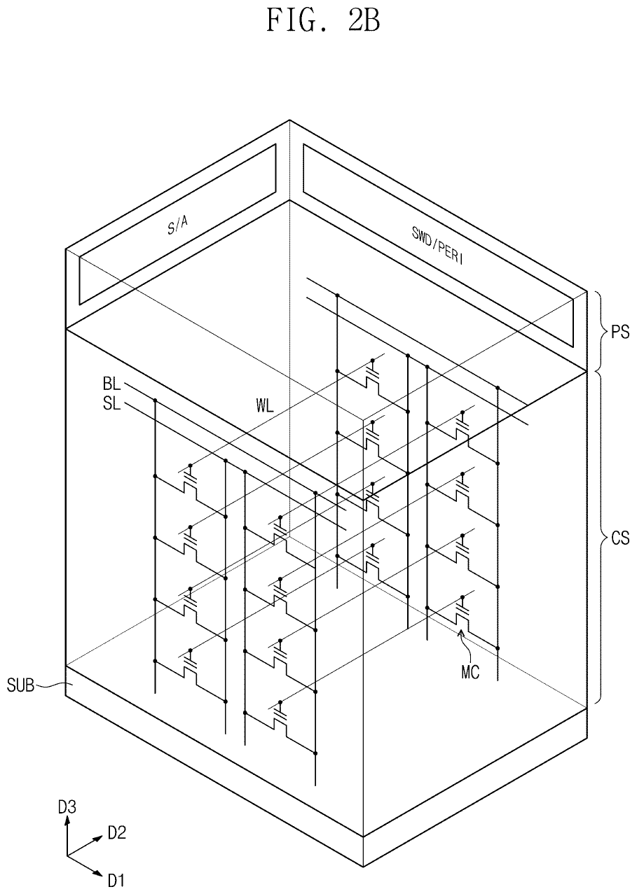

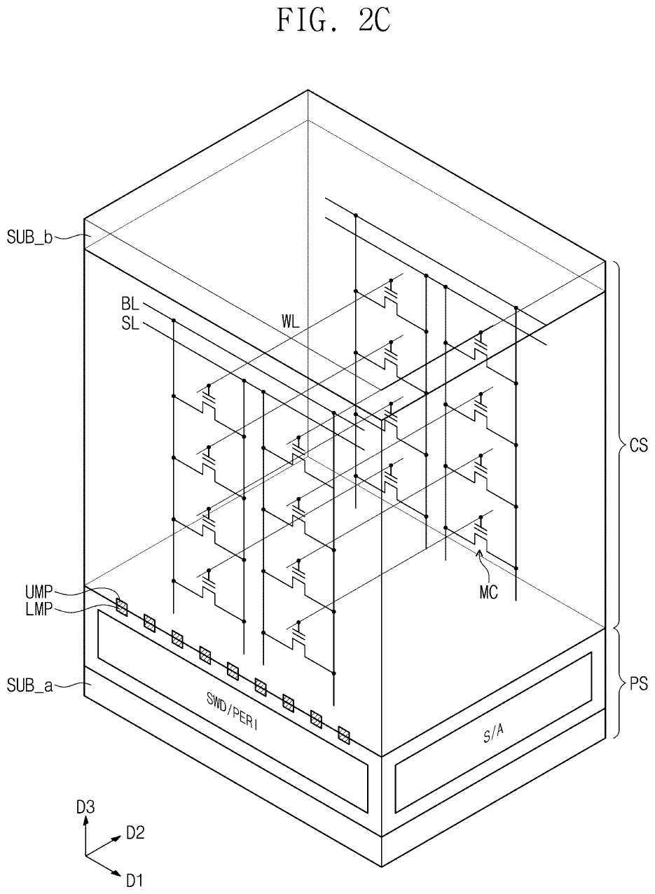

FIGS. 2A, 2B, and 2C are perspective views schematically illustrating a three-dimensional semiconductor device according to an embodiment of inventive concepts.

Referring to FIG. 2A, a three-dimensional semiconductor device may include a substrate SUB, a peripheral circuit structure PS on the substrate SUB, and a cell array structure CS on the peripheral circuit structure PS.

The peripheral circuit structure PS may include core and peripheral circuits SWD/PERI and S/A formed on the substrate SUB. The core and peripheral circuits may include the row and column decoders 2 and 4, the sense amplifier 3, and the control logic 5 described with reference to FIG. 1.

The substrate SUB may be a plate-shaped structure that extends parallel to a plane defined by a first direction D1 and a second direction D2. The first and second directions D1 and D2 may be parallel to a bottom surface of the substrate SUB and may not be parallel to each other. As an example, the first and second directions D1 and D2 may be horizontal directions that are orthogonal to each other. The peripheral circuit structure PS and the cell array structure CS may be sequentially stacked on the substrate SUB in a vertical direction D3 perpendicular to the bottom surface of the substrate SUB.

The cell array structure CS may include the bit lines BL, the source lines SL, the word lines WL, and the memory cells MC therebetween. Each of the memory cells MC may be connected to one of the word lines WL, one of the bit lines BL, and one of the source lines SL.

Referring to FIG. 2B, a semiconductor device may include the cell array structure CS on the substrate SUB and the peripheral circuit structure PS on the cell array structure CS. The cell array structure CS may be disposed between the substrate SUB and the peripheral circuit structure PS. The peripheral circuit structure PS may include core and peripheral circuits SWD/PERI and S/A.

Referring to FIG. 2C, a semiconductor device may have a chip-to-chip (C2C) structure. The peripheral circuit structure PS may include a lower substrate SUB_a. Lower metal pads LMP may be provided in the uppermost portion of the peripheral circuit structure PS. The lower metal pads LMP may be electrically connected to the core and peripheral circuits. The lower metal pads LMP may be bonded to upper metal pads UMP of the cell array structure CS. The peripheral circuit structure PS may include core and peripheral circuits SWD/PERI and S/A.

The cell array structure CS may include an upper substrate SUB_b, and the upper metal pads UMP may be provided in the lowermost portion of the cell array structure CS. The upper metal pads UMP may be electrically connected to the bit lines BL, the source lines SL, and the word lines WL. The upper metal pads UMP may be electrically connected to the memory cells MC.

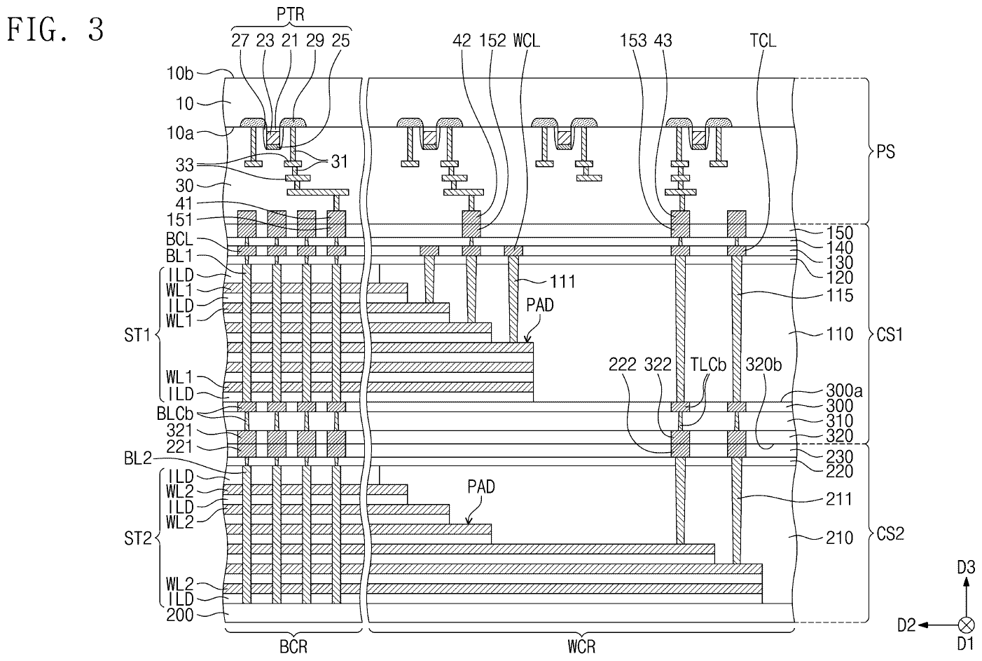

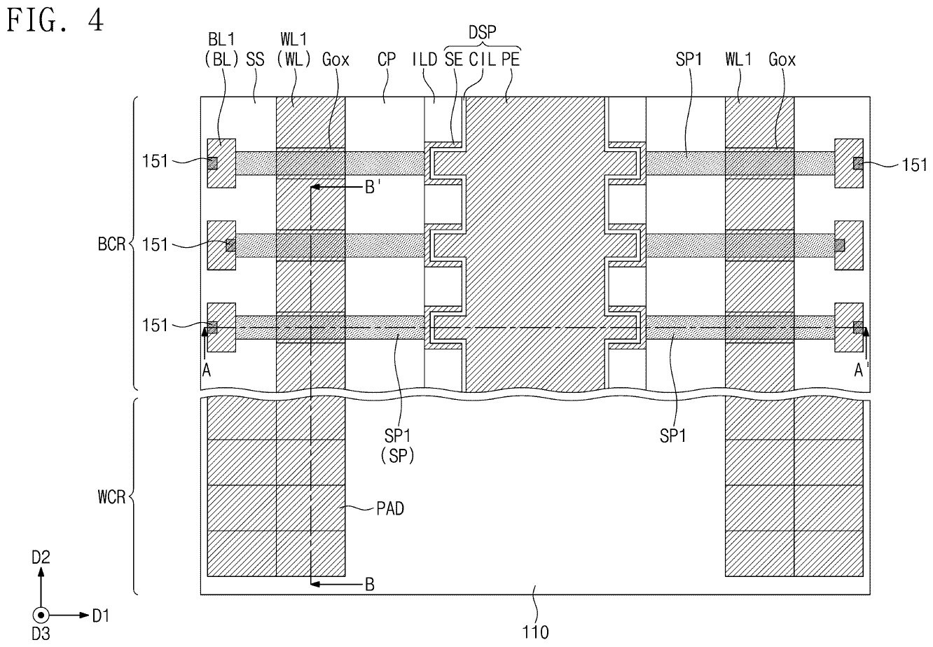

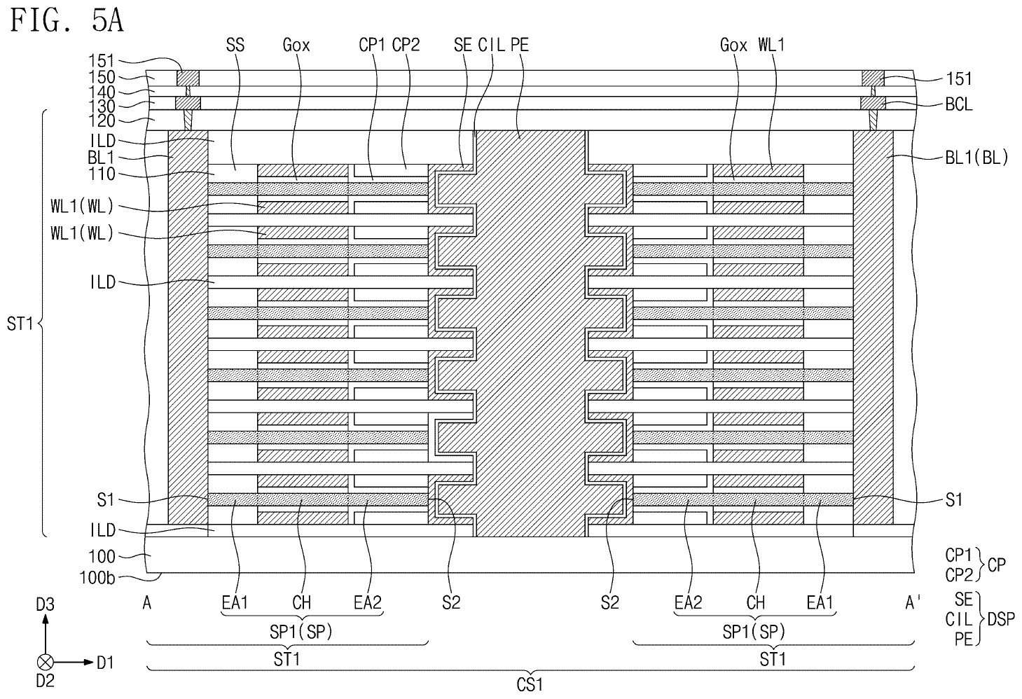

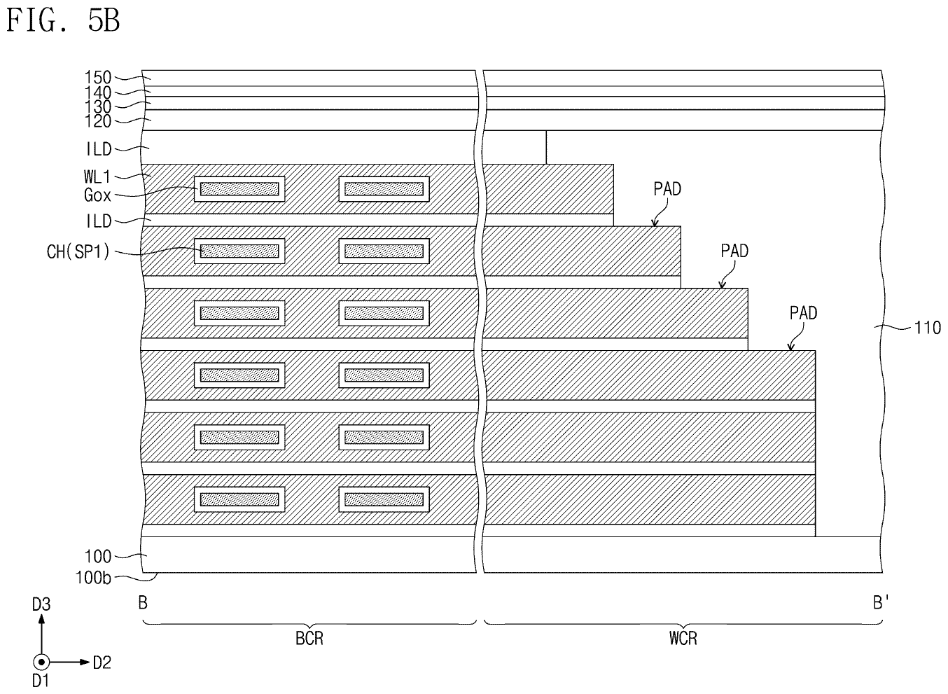

FIG. 3 is a sectional view illustrating a three-dimensional semiconductor device according to an embodiment of inventive concepts. FIG. 4 is a plan view illustrating a three-dimensional semiconductor device according to an embodiment of inventive concepts. FIG. 5A is a sectional view corresponding to a line A-A′ of FIG. 3. FIG. 5B is a sectional view corresponding to a line B-B′ of FIG. 3.

Referring to FIG. 3, a three-dimensional semiconductor device may include a first cell array structure CS1, a second cell array structure CS2, and the peripheral circuit structure PS on the first cell array structure CS1. The second cell array structure CS2 may be spaced apart from the peripheral circuit structure PS with the first cell array structure CS1 interposed therebetween. For example, the first cell array structure CS1 may be disposed on the second cell array structure CS2, and the peripheral circuit structure PS may be disposed on the first cell array structure CS1.

The three-dimensional semiconductor device may include three chips that are bonded to each other. In an embodiment, a first chip including the first cell array structure CS1 may be fabricated on a first wafer, a second chip including the second cell array structure CS2 may be fabricated on a second wafer, and a third chip including the peripheral circuit structure PS may be fabricated on a third wafer. Next, the first to third chips may be connected to each other. In an embodiment, the connection of the first to third chips may be achieved by a bonding method. The bonding method may mean a method of electrically connecting a bonding metal of the upper chip to a bonding metal of the lower chip. The bonding metal of the upper chip may be formed in the uppermost metal layer of the upper chip and the bonding metal of the lower chip may be formed in the uppermost metal layer of the lower chip.

Each of the first and second cell array structures CS1 and CS2 may include a bit line connection region BCR and a word line connection region WCR. The first and second cell array structures CS1 and CS2 may include stacks ST1 and ST2, respectively. Each of the stacks ST1 and ST2 may include semiconductor patterns SP, word lines WL, bit lines BL, gate insulating layers Gox, and a data storage pattern DSP. Hereinafter, the first cell array structure CS1 will be described for brevity, but the second cell array structure CS2 may have substantially the same features.

Referring to FIGS. 4, 5A, and 5B, the first cell array structure CS1 may be disposed on the first substrate 100. In an embodiment, the first substrate 100 may be a semiconductor substrate, an insulating substrate, or a semiconductor on insulator substrate (e.g. a silicon-on-insulator (SOI) substrate or a germanium-on-insulator (GOI) substrate). The semiconductor substrate may be, for example, a silicon substrate, a germanium substrate, or a silicon-germanium substrate. The first substrate 100 may be a plate-shaped structure that extends parallel to a plane defined by the first and second directions D1 and D2. In the present specification, the first and second directions D1 and D2 may be parallel to a bottom surface 100b of the first substrate 100 and may not be parallel to each other. Alternatively, the first and second directions D1 and D2 may be parallel to a bottom surface 320b of lower insulating layers 300, 310, and 320, which will be described below, and may not be parallel to each other. A third direction D3 may be the vertical direction D3 that is perpendicular to the bottom surface 100b of the first substrate 100 or a top surface 300a of the lower insulating layers 300, 310, and 320. In an embodiment, the first to third directions D1, D2, and D3 may be orthogonal to each other.

The first cell array structure CS1 may include first stacks ST1, which are spaced apart from each other in the first direction D1, and the data storage pattern DSP, which is provided therebetween. Although not shown, the first cell array structure CS1 may include a plurality of cell array structures, which are spaced apart from each other in the first direction D1. Hereinafter, for convenience in description, one of the cell array structures will be described for brevity, and the others of the cell array structures may have substantially the same features.

Each of the first stacks ST1 may include semiconductor patterns SP, word lines WL, bit lines BL, gate insulating layers Gox, first capping patterns CP1, second capping patterns CP2, interlayer insulating patterns ILD, and a planarization insulating layer 110. In an embodiment, the first stacks ST1 may be provided to have a mirror symmetry with respect to the data storage pattern DSP. The semiconductor patterns SP, the word lines WL, the bit lines BL, and the planarization insulating layer 110 of the first cell array structure CS1 may be referred to as first semiconductor patterns SP1, first word lines WL1, first bit lines BL1, and the first planarization insulating layer 110, respectively. Hereinafter, for convenience in description, one of the first stacks ST1 will be described for brevity, but the others of the first stacks ST1, which are spaced apart from the same in the first direction D1, may have substantially the same features.

The first semiconductor pattern SP1 may be extended in the first direction D1, on the first substrate 100. The first semiconductor pattern SP1 may be spaced apart from the first substrate 100 in the third direction D3. In other words, the first semiconductor pattern SP1 may be electrically floated from the first substrate 100. In an embodiment, a plurality of first semiconductor patterns SP1 may be provided. The first semiconductor patterns SP1 may be spaced apart from each other in the second and third directions D2 and D3. The first semiconductor patterns SP1, which are spaced apart from each other in the third direction D3, may be vertically overlapped with each other, when viewed in a plan view. Side surfaces of the first semiconductor patterns SP1, which are spaced apart from each other in the third direction D3, may be aligned to each other in the third direction D3.

The first semiconductor pattern SP1 may include a first edge portion EA1 and a second edge portion EA2, which are spaced apart from each other in the first direction D1, and a channel region CH therebetween. The channel region CH of the first semiconductor pattern SP1 may be surrounded by the first word line WL1. The first edge portion EA1 of the first semiconductor pattern SP1 may be adjacent to the first bit line BL1. The first edge portion EA1 may be electrically connected to the first bit line BL1. The second edge portion EA2 may be adjacent to the data storage pattern DSP. The second edge portion EA2 may be electrically connected to the data storage pattern DSP.

The first semiconductor pattern SP1 may have a first side surface S1 and a second side surface S2, which are opposite to each other in the first direction D1. The first side surface S1 may be a side surface of the first edge portion EA1, and the second side surface S2 may be a side surface of the second edge portion EA2. The first side surface S1 of the first semiconductor pattern SP1 may be adjacent to the first bit line BL1, and the second side surface S2 may be adjacent to the data storage pattern DSP.

The first semiconductor pattern SP1 may be formed of or include at least one of single-crystalline semiconductor materials, polycrystalline semiconductor materials, oxide semiconductor materials, and two-dimensional materials. In an embodiment, the single-crystalline semiconductor material may be single-crystalline silicon. In an embodiment, the polycrystalline semiconductor materials may be poly silicon. In an embodiment, the oxide semiconductor materials may be indium gallium zinc oxide (IGZO). In an embodiment, the two-dimensional material may be MoS₂, WS₂, MoSe₂, or WSe₂.

As an example, each of the first and second edge portions EA1 and EA2 of the first semiconductor pattern SP1 may include an impurity region that is doped with impurities (e.g., n- or p-type impurities). The impurity region may be used as a source/drain region of a transistor.

The first word line WL1 may be provided to surround the channel region CH of the first semiconductor pattern SP1 and may be extended in the second direction D2. In an embodiment, the first word line WL1 may have a structure fully surrounding the channel region CH of the first semiconductor pattern SP1 (e.g., a gate-all-around structure). Each first word line WL1 may be provided to surround the channel region CH of each of the first semiconductor patterns SP1, which are spaced apart from each other in the second direction D2. In an embodiment, a plurality of first word lines WL1 may be provided. Each of the first word lines WL1 may be provided to surround the channel region CH of a corresponding one of the first semiconductor patterns SP1, which are spaced apart from each other in the third direction D3, and may be extended in the second direction D2. The first word lines WL1 may be spaced apart from each other in the third direction D3.

The first word lines WL1 may be extended from the bit line connection region BCR to the word line connection region WCR. The first word lines WL1 may include pad portions PAD, which are provided in the word line connection region WCR. The first word lines WL1 may have a staircase structure in the word line connection region WCR. The pad portions PAD of the first word lines WL1 may be placed at different positions in horizontal and vertical directions.

The first word lines WL1 may be formed of or include at least one of doped polysilicon, metallic materials (e.g., Al, Cu, Ti, Ta, Ru, W, Mo, Pt, Ni, and Co), conductive metal nitride materials (e.g., TiN, TaN, WN, NbN, TiAIN, TiSiN, TaSiN, and RuTiN), conductive metal silicide materials, or conductive metal oxide materials (e.g., PtO, RuO₂, IrO₂, SrRuO₃ (SRO), (Ba,Sr)RuO₃ (BSRO), CaRuO₃ (CRO), and (La,Sr)CoO₃ (LSCo)), but inventive concepts are not limited to this example. The first word lines WL may be a single or multiple layer made of at least one of the afore-described materials. In an embodiment, the first word lines WL may be formed of or include at least one of two-dimensional semiconductor materials (e.g., graphene, carbon nanotube, or combinations thereof).

A gate insulating layer Gox may be interposed between the first word line WL1 and the first semiconductor pattern SP1. The gate insulating layer Gox may surround the first semiconductor pattern SP1. The first word line WL1 on the gate insulating layer Gox may surround the channel region CH of the first semiconductor pattern SP1. In an embodiment, a plurality of gate insulating layers Gox may be provided. Each of the gate insulating layers Gox may be provided to surround a corresponding one of the first semiconductor patterns SP1.

The gate insulating layer Gox may be formed of or include at least one of silicon oxide, silicon oxynitride, or high-k dielectric materials whose dielectric constants are higher than that of silicon oxide. The high-k dielectric material may include metal oxide materials or metal oxynitride materials. For example, the high-k dielectric material, which is used as the gate insulating layer Gox, may include at least one of HfO₂, HfSiO, HfSiON, HfTaO, HfTiO, HfZrO, ZrO₂, or Al₂O₃, but inventive concepts are not limited to this example. The high-k dielectric material may be defined as a material having a dielectric constant higher than silicon oxide.

The first bit line BL1 may be provided on the first side surface S1 of the first semiconductor pattern SP1. The first bit line BL1 may be extended from the first side surface S1 of the first semiconductor pattern SP1 in the third direction D3. Accordingly, each of the first bit lines BL1 may be in contact with the first side surface S1 of each of the first semiconductor patterns SP1, which are spaced apart from each other in the third direction D3, and may be electrically connected to the first semiconductor patterns SP1.

The first bit line BL1 may be formed of or include at least one of doped polysilicon, metallic materials (e.g., Al, Cu, Ti, Ta, Ru, W, Mo, Pt, Ni, and Co), conductive metal nitride materials (e.g., TiN, TaN, WN, NbN, TiAIN, TiSiN, TaSIN, and RuTiN), conductive metal silicide materials, or conductive metal oxide materials (e.g., PtO, RuO₂, IrO₂, SrRuO₃ (SRO), (Ba,Sr) RuO₃ (BSRO), CaRuO₃ (CRO), and (La,Sr) CoO₃ (LSCo)), but inventive concepts are not limited to this example. The bit line BL may be provided to have a single- or multi-layered structure formed of the afore-described materials. In an embodiment, the bit line BL may be formed of or include at least one of two-dimensional semiconductor materials (e.g., graphene, carbon nanotube, or combinations thereof).

The first bit lines BL1 may be provided in the bit line connection region BCR.

The interlayer insulating pattern ILD may be disposed between the first word lines WL1, which are adjacent to each other in the third direction D3. The first word lines WL1 may be spaced apart from each other in the third direction D3 by the interlayer insulating pattern ILD. A side surface of the interlayer insulating pattern ILD may be in contact with a side surface of the first bit line BL1. An opposite side surface of the interlayer insulating pattern ILD may protrude beyond the second side surface S2 of the first semiconductor pattern SP1 in the first direction D1. In an embodiment, a plurality of interlayer insulating patterns ILD may be provided. The first stack ST1 may have a structure, in which the first word lines WL1 and the interlayer insulating patterns ILD are alternately stacked in the third direction D3. The interlayer insulating patterns ILD may be extended from the bit line connection region BCR to the word line connection region WCR. The interlayer insulating patterns ILD may have a staircase structure in the word line connection region WCR. A side surface of each of the interlayer insulating patterns ILD may be aligned to a side surface of the first word line WL1, which is placed thereon and is in contact with the same, in the third direction D3. The interlayer insulating pattern ILD may include a single or composite layer including an insulating material.

Spacer patterns SS may be respectively disposed between the interlayer insulating patterns ILD, which are adjacent to each other in the third direction D3, and between the first bit line BL1 and the first word lines WL1. Each of the spacer patterns SS may be provided to surround the first edge portion EA1 of the first semiconductor pattern SP1. The spacer pattern SS may include a single or composite layer including an insulating material.

The data storage pattern DSP may be interposed between the first stacks ST1, which are spaced apart from each other in the first direction D1. The data storage pattern DSP may be interposed between the first semiconductor patterns SP1, which are spaced apart from each other in the first direction D1. The data storage pattern DSP may be in contact with the second side surfaces S2 of the first semiconductor patterns SP1 and may be electrically connected to the first semiconductor patterns SP1.

The data storage pattern DSP may include a storage electrode SE, a plate electrode PE, and a capacitor dielectric layer CIL interposed therebetween. As an example, the three-dimensional semiconductor device may be a dynamic random access memory (DRAM) device and the data storage pattern DSP may be a capacitor. The storage electrode SE may be spaced apart from the plate electrode PE, with the capacitor dielectric layer CIL interposed therebetween.

Each of the storage and plate electrodes SE and PE may include a conductive material. In an embodiment, each of the storage and plate electrodes SE and PE may be formed of or include at least one of doped silicon (Si), doped silicon germanium (SiGe), metallic materials (e.g., Ti, Mo, W, Cu, Al, Ta, Ru, Ir, Co, Pt, Au, and Ag), metal nitride materials (e.g., nitride materials containing Ti, Mo, W, Cu, Al, Ta, Ru, Ir, Co, Pt, Au, and Ag, titanium silicon nitride (TiSiN), titanium aluminum nitride (TiAIN), and tantalum aluminum nitride (TaAIN)), conductive oxide materials (e.g., PtO, RuO₂, IrO₂, SrRuO₃ (SRO), (Ba,Sr) RuO₃ (BSRO), CaRuO₃ (CRO), and LSCo), or metal silicide materials. Each of the storage and plate electrodes SE and PE may be a single layer made of a single material or a composite layer including two or more materials.

In an embodiment, the capacitor dielectric layer CIL may include at least one of metal oxide materials (e.g., HfO₂, ZrO₂, Al₂O₃, La₂O₃, Ta₂O₃, and TiO₂), perovskite dielectric materials (e.g., SrTiO₃ (STO), (Ba,Sr) TiO₃ (BST), BaTiO₃, lead zirconium titanate (PZT), and lead lanthanum zirconium titanate (PLZT)).

In another embodiment, the data storage pattern DSP may be a variable resistance pattern whose resistance can be switched to one of at least two states by an electric pulse applied thereto. For example, the data storage pattern DSP may be formed of or include at least one of phase-change materials whose crystal state can be changed depending on an amount of a current applied thereto, perovskite compounds, transition metal oxide materials, magnetic materials, ferromagnetic materials, or antiferromagnetic materials.

The storage electrode SE may have a hollow cup shape. Although not shown, a silicide pattern (not shown) may be provided between the storage electrode SE and the first semiconductor pattern SP1. The silicide pattern may be formed of or include at least one of metal silicide materials (e.g., containing Ti, Mo, W, Cu, Al, Ta, Ru, Ir, and Co). In an embodiment, a plurality of storage electrodes SE may be provided and may be spaced apart from each other in the third direction D3. Each of the storage electrodes SE may be disposed to be in contact with the second side surface S2 of a corresponding one of the semiconductor patterns SP. The storage electrodes SE may be respectively disposed between vertically adjacent ones of the interlayer insulating patterns ILD.

The plate electrode PE may include a stem portion, which is extended in the third direction D3, and branch portions, which are extended from the stem portion to protrude in the first direction D1 or an opposite direction thereof. The branch portions of the plate electrode PE may be disposed to fill the cup-shaped regions of the storage electrodes SE, respectively.

The first planarization insulating layer 110 may be disposed in the word line connection region WCR and on the first substrate 100. The first planarization insulating layer 110 may cover the staircase structure of the first stack ST1. In other words, the first planarization insulating layer 110 may cover the pad portions PAD of the first word lines WL1.

A capping pattern CP may be provided in the first cell array structure CS1. The capping pattern CP may be interposed between the first word lines WL1 and the data storage pattern DSP. The capping pattern CP may be interposed between the interlayer insulating patterns ILD, which are adjacent to each other in the third direction D3. The capping pattern CP may surround the second edge portion EA2.

The capping pattern CP may include a first capping pattern CP1 surrounding the second edge portion EA2 of the semiconductor pattern SP and a second capping pattern CP2 on the first capping pattern CP1. The first capping pattern CP1 may conformally cover the second edge portion EA2 of the semiconductor pattern SP, the side surface of the first word line WL1, and the side surface of the gate insulating layer Gox. Each of the first and second capping patterns CP1 and CP2 may include an insulating material. The second capping pattern CP2 may include a single layer or a composite layer.

First upper insulating layers 120, 130, 140, and 150 may be provided on the first stack ST1. The first upper insulating layers 120, 130, 140, and 150 may cover top surfaces of the first stacks ST1 and a top surface of the data storage pattern DSP. The first upper insulating layers 120, 130, 140, and 150 may include a plurality of insulating layers. Upper connection lines BCL may be provided in the first upper insulating layers 120, 130, 140, and 150.

Upper bonding pads 151 may be disposed in the first upper insulating layers 120, 130, 140, and 150. In an embodiment, the upper bonding pads 151 may include first upper bonding pads 151. Each of the first upper bonding pads 151 may be electrically connected to a corresponding one of the first bit lines BL1 through the upper connection line BCL. When viewed in a plan view, the first upper bonding pads 151, which are adjacent to each other in the second direction D2, may be offset from each other in the first direction D1. The first upper bonding pads 151 may be disposed to form a zigzag shape in the second direction D2, when viewed in a plan view.

Referring back to FIG. 3, the first substrate 100 may be removed from the first cell array structure CS1, and then, the lower insulating layers 300, 310, and 320 may be provided. The lower insulating layers 300, 310, and 320 may be composed of a plurality of insulating layers.

The second cell array structure CS2 may be disposed on the bottom surface 320b of the lower insulating layers 300, 310, and 320 of the first cell array structure CS1. The lower insulating layers 300, 310, and 320 of the first cell array structure CS1 may be disposed to be adjacent to the second cell array structure CS2. The second cell array structure CS2 may include a second substrate 200 and a second stack ST2 on the second substrate 200. The second cell array structure CS2 may include substantially the same elements as those in the first cell array structure CS1. For example, the second cell array structure CS2 may include second semiconductor patterns, second word lines WL2, second bit lines BL2, a data storage pattern, interlayer insulating patterns ILD, and a second planarization insulating layer 210, which are configured to have substantially the same features as the first semiconductor patterns SP1, the first word lines WL1, the first bit lines BL1, the data storage pattern DSP, the interlayer insulating patterns ILD, and the first planarization insulating layer 110 of the first cell array structure CS1. In other words, the first stack ST1 of the first cell array structure CS1 may have the same structure as the second stack ST2 of the second cell array structure CS2. Second upper insulating layers 220 and 230 may be disposed on the second stack ST2. The second upper insulating layers 220 and 230 may be composed of a plurality of insulating layers. The second upper insulating layers 220 and 230 may be disposed adjacent to the first cell array structure CS1.

The first cell array structure CS1 may include a penetration contact plug 115 penetrating the first planarization insulating layer 110. The penetration contact plug 115 may be disposed in the word line connection region WCR.

Lower connection lines BCLb and TCLb and lower interconnection lines may be disposed in the lower insulating layers 300, 310, and 320 of the first cell array structure CS1. The lower connection lines BCLb and TCLb and the lower interconnection lines may be electrically connected to the first bit lines BL1 and the penetration contact plug 115 of the first cell array structure CS1. In an embodiment, the first lower connection line BCLb may be electrically connected to the first bit line BL1. The second lower connection line TCLb may be electrically connected to the penetration contact plug 115.

Lower bonding pads 321 and 322 may be disposed in the lower insulating layers 300, 310, and 320. The lower bonding pads 321 and 322 may be electrically connected to the lower connection lines BCLb and TCLb and the lower interconnection lines and may also be electrically connected to the first bit lines BL1 and the penetration contact plug 115. Bottom surfaces of the lower bonding pads 321 and 322 may not be covered with the lower insulating layers 300, 310, and 320 and may be exposed to the outside of the first cell array structure CS1. Bottom surfaces of the lower bonding pads 321 and 322 may be coplanar with the bottom surface 320b of the lower insulating layers 300, 310, and 320. In an embodiment, the lower bonding pads 321 and 322 may include a first lower bonding pad 321, which is connected to the first bit line BL1 in the bit line connection region BCR, and a second lower bonding pad 322, which is connected to the penetration contact plug 115 in the word line connection region WCR. In an embodiment, a plurality of first and second lower bonding pads 321 and 322 may be provided. Although not shown, the first lower bonding pads 321 may be disposed in a zigzag shape, like the first upper bonding pads 151. In an embodiment, additional lower bonding pads may be further provided for an electric connection of the first cell array structure CS1, unlike the illustrated structure.

The second cell array structure CS2 may include a second word line contact 211, which is provided to penetrate the second planarization insulating layer 210 and is connected to the second word line WL2. The second word line contact 211 may be electrically connected to the second word line WL2 through the pad portion PAD of the second word line WL2. In an embodiment, a plurality of second word line contacts 211 may be provided. The second word line contacts 211 may be connected to the second word lines WL2, respectively.

The second cell array structure CS2 may include upper interconnection lines, which are provided in the second upper insulating layers 220 and 230. The upper interconnection lines may be electrically connected to the second word lines WL2 through the second bit lines BL2, the data storage pattern DSP, and the second word line contact 211.

Cell bonding pads 221 and 222 may be disposed in the second upper insulating layer 230. The cell bonding pads 221 and 222 may be electrically connected to the upper interconnection lines, and thus, they may also be electrically connected to the second bit lines BL2 and the second word lines WL2. The cell bonding pads 221 and 222 may have top surfaces, which are not covered with the second upper insulating layers 220 and 230 and may be exposed to the outside of the second cell array structure CS2. The top surfaces of the cell bonding pads 221 and 222 may be coplanar with the top surfaces of the second upper insulating layers 220 and 230. In an embodiment, the cell bonding pads 221 and 222 may include a first cell bonding pad 221, which is provided in the bit line connection region BCR and is connected to the second bit line BL2, and a second cell bonding pad 222, which is provided in the word line connection region WCR and is connected to the second word line WL2 through the second word line contact 211. In an embodiment, a plurality of first and second cell bonding pads 221 and 222 may be provided. Although not shown, the first cell bonding pads 221 may be disposed in a zigzag shape, like the first upper bonding pads 151. In an embodiment, additional cell bonding pads may be further provided for an electric connection of the second cell array structure CS2, unlike the illustrated structure.

The lower bonding pads 321 and 322 of the first cell array structure CS1 may be in direct contact with the cell bonding pads 221 and 222 of the second cell array structure CS2. For example, the lower bonding pads 321 and 322 may be connected to the cell bonding pads 221 and 222 by a bonding method. Each pair of pads, which are respectively included in the lower bonding pads 321 and 322 and the cell bonding pads 221 and 222, may form a single object without any interface therebetween. The lower bonding pads 321 and 322 and the cell bonding pads 221 and 222 are illustrated to have side surfaces aligned to each other, but in an embodiment, the side surfaces of the lower bonding pads 321 and 322 may be spaced apart from the side surfaces of the cell bonding pads 221 and 222, when viewed in a plan view. The lower bonding pads 321 and 322 and the cell bonding pads 221 and 222 may include at least one of metallic materials (e.g., copper (Cu), tungsten (W), aluminum (Al), nickel (Ni), and tin (Sn)). For example, the lower bonding pads 321 and 322 and the cell bonding pads 221 and 222 may be formed of or include copper (Cu). In an embodiment, the first lower bonding pad 321 may be in direct contact with the first cell bonding pad 221. The second lower bonding pad 322 may be in direct contact with the second cell bonding pad 222.

The first cell array structure CS1 may include a first word line contact 111, which is provided to penetrate the first planarization insulating layer 110 and is connected to the first word line WL1. The first word line contact 111 may be electrically connected to the first word line WL1 through the pad portion PAD of the first word line WL1. In an embodiment, a plurality of first word line contacts 111 may be provided. The first word line contacts 111 may be connected to the first word lines WL1, respectively.

The first cell array structure CS1 may include upper connection lines BCL, WCL, and TCL disposed in the first upper insulating layers 120, 130, 140, and 150. In an embodiment, the first upper connection line BCL may be electrically connected to the first bit line BL1, in the bit line connection region BCR. The second upper connection line WCL may be electrically connected to the first word line WL1 through the first word line contact 111. The third upper connection line TCL may be electrically connected to the penetration contact plug 115.

Upper bonding pads 151, 152, and 153, which are electrically connected to the upper connection lines BCL, WCL, and TCL, may be disposed in the first upper insulating layers 120, 130, 140, and 150. The upper bonding pads 151, 152, and 153 may be electrically connected to the first bit line BL1, the first word line WL1, and the penetration contact plug 115 through the upper connection lines BCL, WCL, and TCL. The upper bonding pads 151, 152, and 153 may have top surfaces, which are not covered with the first upper insulating layers 120, 130, 140, and 150 and are exposed to the outside of the first upper insulating layers 120, 130, 140, and 150. The top surfaces of the upper bonding pads 151, 152, and 153 may be coplanar with the top surfaces of the first upper insulating layers 120, 130, 140, and 150. In an embodiment, the upper bonding pads 151, 152, and 153 may include a first upper bonding pad 151, which is provided in the bit line connection region BCR and is connected to the first bit line BL1, a second upper bonding pad 152, which is provided in the word line connection region WCR and is connected to the first word line WL1, and a third upper bonding pad 153, which is provided in the word line connection region WCR and is electrically connected to the penetration contact plug 115. In an embodiment, a plurality of first to third upper bonding pads 151, 152, and 153 may be provided. In addition, the first upper bonding pads 151 may be disposed in a zigzag shape, as described with reference to FIG. 4. In an embodiment, additional upper bonding pads may be further provided for an electric connection of the first cell array structure CS1, unlike the illustrated structure.

The peripheral circuit structure PS may be disposed on the first upper insulating layers 120, 130, 140, and 150 of the first cell array structure CS1. The peripheral circuit structure PS may include a peripheral substrate 10, peripheral circuit transistors PTR and peripheral contact plugs 31, which are provided on the peripheral substrate 10, peripheral circuit interconnection lines 33, which are electrically connected to the peripheral circuit transistors PTR through the peripheral contact plugs 31, and a first insulating layer 30 enclosing them.

The peripheral circuit transistors PTR, the peripheral contact plugs 31, and the peripheral circuit interconnection lines 33 may constitute a peripheral circuit. Each of the peripheral circuit transistors PTR may include a peripheral gate insulating layer 21, a peripheral gate electrode 23, a peripheral capping pattern 25, a peripheral gate spacer 27, and peripheral source/drain regions 29.

The peripheral gate insulating layer 21 may be disposed between the peripheral gate electrode 23 and the peripheral substrate 10. The peripheral capping pattern 25 may be disposed on the peripheral gate electrode 23. The peripheral gate spacer 27 may be provided to cover side surfaces of the peripheral gate insulating layer 21, the peripheral gate electrode 23, and the peripheral capping pattern 25. The peripheral source/drain regions 29 may be provided in portions of the peripheral substrate 10 which are located at both sides of the peripheral gate electrode 23.

The peripheral circuit interconnection lines 33 may be electrically connected to the peripheral circuit transistors PTR through the peripheral contact plugs 31. Each of the peripheral circuit transistors PTR may be an NMOS transistor, a PMOS transistor, or a gate-all-around transistor. The peripheral contact plugs 31 and the peripheral circuit interconnection lines 33 may include at least one of metal or conductive materials.

The first insulating layer 30 may be provided on a top surface 10a of the peripheral substrate 10. The peripheral substrate 10 may have a top surface 10a and a bottom surface 10b, which are opposite to each other in the vertical direction D3. FIG. 3 illustrates an inverted structure of the peripheral circuit structure PS. The first insulating layer 30 on the peripheral substrate 10 may cover the peripheral circuit transistors PTR, the peripheral contact plugs 31, and the peripheral circuit interconnection lines 33. The first insulating layer 30 may be provided to have a multi-layered structure including a plurality of insulating layers. For example, the first insulating layer 30 may be formed of or include at least one of silicon oxide, silicon nitride, silicon oxynitride, and/or low-k dielectric materials.

Peripheral bonding pads 41, 42, and 43, which are electrically connected to the peripheral circuit transistors PTR through the peripheral contact plugs 31 and the peripheral circuit interconnection lines 33, may be disposed in the first insulating layer 30. The peripheral bonding pads 41, 42, and 43 may have top surfaces, which are not covered with the first insulating layer 30 and are exposed to the outside of the peripheral circuit structure PS. The top surfaces of the peripheral bonding pads 41, 42, and 43 may be coplanar with a top surface of the first insulating layer 30. In an embodiment, the peripheral bonding pads 41, 42, and 43 may include a first peripheral bonding pad 41, a second peripheral bonding pad 42, and a third peripheral bonding pad 43. In an embodiment, the first to third peripheral bonding pads 41, 42, and 43 may be provided in plural. In an embodiment, additional peripheral bonding pads may be further provided for an electric connection of the peripheral circuit structure PS, unlike the illustrated structure.

The upper bonding pads 151, 152, and 153 of the first cell array structure CS1 may be in direct contact with the peripheral bonding pads 41, 42, and 43 of the peripheral circuit structure PS. In other words, the upper bonding pads 151, 152, and 153 and the peripheral bonding pads 41, 42, and 43 may be connected to each other by a bonding method. Each pair of pads, which are respectively included in the upper bonding pads 151, 152, and 153 and the peripheral bonding pads 41, 42, and 43, may form a single object without an interface therebetween. The upper bonding pads 151, 152, and 153 and the peripheral bonding pads 41, 42, and 43 are illustrated to have side surfaces aligned to each other, but in an embodiment, the side surfaces of the upper bonding pads 151, 152, and 153 may be spaced apart from the side surfaces of the peripheral bonding pads 41, 42, and 43, when viewed in a plan view. The upper bonding pads 151, 152, and 153 and the peripheral bonding pads 41, 42, and 43 may include at least one of metallic materials (e.g., copper (Cu), tungsten (W), aluminum (Al), nickel (Ni), and tin (Sn)). For example, the upper bonding pads 151, 152, and 153 and the peripheral bonding pads 41, 42, and 43 may be formed of or include copper (Cu). In an embodiment, the first upper bonding pad 151 may be in direct contact with the first peripheral bonding pad 41. The second upper bonding pad 152 may be in direct contact with the second peripheral bonding pad 42. The third upper bonding pad 153 may be in direct contact with the third peripheral bonding pad 43.

Since the first cell array structure CS1 is connected to the peripheral circuit structure PS by a bonding method, the second cell array structure CS2 may be electrically connected to the peripheral circuit structure PS. In an embodiment, the second word line WL2 of the second cell array structure CS2 may be electrically connected to the peripheral circuit structure PS through the second cell bonding pad 222, the second lower bonding pad 322, the penetration contact plug 115, the third upper bonding pad 153, and the third peripheral bonding pad 43.

According to an embodiment of inventive concepts, generation extension may be achieved by a method of bonding cell structures to each other, not by a simple method of increasing the number of stacks. In other words, by connecting the first cell array structure CS1 to the second cell array structure CS2 using a bonding method, it may be possible to easily increase an integration density of the semiconductor device. This may make it possible to solve various issues, such as high process difficulty, long fabrication time, and high fabrication cost, in a simple stacking scheme. In other words, by separately fabricating the first and second cell array structures CS1 and CS2 and bonding them to each other, it may be possible to effectively reduce the difficulty, time, and cost of the fabrication process. In addition, since the first upper bonding pads 151 are disposed in a zigzag shape, it may be possible to increase a bonding margin.

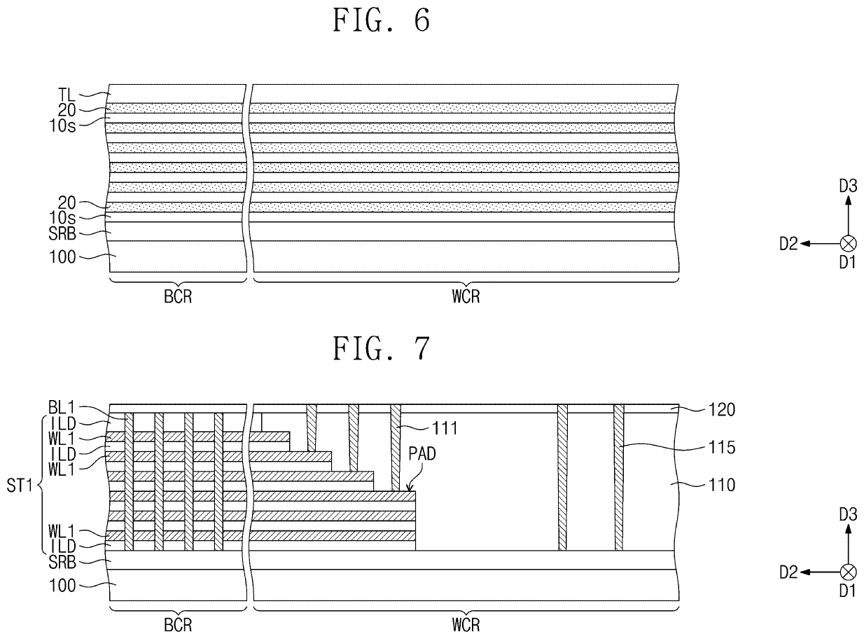

FIGS. 6 to 12 are sectional views illustrating a method of fabricating a three-dimensional semiconductor device, according to an embodiment of inventive concepts. Hereinafter, a method of fabricating a three-dimensional semiconductor device, according to an embodiment of inventive concepts, will be described in more detail with reference to FIGS. 6 to 12. For concise description, a previously described element may be identified by the same reference number without repeating an overlapping description thereof.

Referring to FIG. 6, a buffer layer SRB may be formed on the first substrate 100. The buffer layer SRB may be formed on the entire top surface of the first substrate 100. The buffer layer SRB may be formed of or include silicon-germanium (SiGe). The germanium concentration in the buffer layer SRB may range from about 1 at % to about 15 at %. The buffer layer SRB may be formed by a selective epitaxial growth process.

First semiconductor layers 10s and second semiconductor layers 20 may be alternatingly stacked on the buffer layer SRB. The first semiconductor layers 10s may be formed of or include at least one of, for example, silicon, germanium, silicon-germanium, or indium gallium zinc oxide (IGZO). In an embodiment, the first semiconductor layers 10s may include the same semiconductor material as the first substrate 100. For example, the first semiconductor layers 10s may be formed by an epitaxial growth method and may be a single crystalline silicon layer.

The second semiconductor layers 20 may be formed of or include at least one of, for example, silicon germanium, silicon oxide, silicon nitride, or silicon oxynitride. In an embodiment, the second semiconductor layers 20 may be formed by an epitaxial growth method and may be, for example, a silicon germanium layer. In the case where the second semiconductor layers 20 include silicon germanium, the germanium concentration in the second semiconductor layer 20 may be higher than the germanium concentration in the buffer layer SRB. For example, the germanium concentration in the second semiconductor layer 20 may range from about 15 at % to about 30 at %. A thickness of the second semiconductor layer 20 may be substantially equal to or less than a thickness of the first semiconductor layer 10s.

The uppermost insulating layer TL may be formed to cover the uppermost one of the second semiconductor layers 20. The uppermost insulating layer TL may be formed of an insulating material having an etch selectivity with respect to the first semiconductor layers 10s and the second semiconductor layers 20. For example, the uppermost insulating layer TL may be a silicon oxide layer.

Referring to FIG. 7, the second semiconductor layers 20 may be replaced with the interlayer insulating patterns ILD, and the first semiconductor patterns SP1 and word lines WL1 may be formed from the first semiconductor layers 10s.

In an embodiment, the first semiconductor patterns SP1 may be formed by leaving portions of the first semiconductor layers 10s, and then, the first word lines WL1 may be formed.

Before the forming of the first word lines WL1, a patterning process may be performed on the first and second semiconductor layers 10 and 20, and a staircase structure may be formed in the word line connection region WCR by the patterning process. Thus, the first planarization insulating layer 110 may be formed to cover the staircase structure, and then, by performing replacement processes, the first word lines WL1 may have a staircase structure in the word line connection region WCR. Here, the buffer layer SRB may be exposed during the patterning process on the first and second semiconductor layers 10 and 20, and thus, the first planarization insulating layer 110 may be formed on the buffer layer SRB.

Each of the first word lines WL1 may be disposed between vertically adjacent ones of the interlayer insulating patterns ILD.

The first bit lines BL1 may be formed after the formation of the first word lines WL1. The first bit lines BL1 may be in contact with the first side surfaces S1 of the first semiconductor patterns SP1, as described above.

After the formation of the first bit lines BL1, the first upper insulating layer 120 may be formed on the first planarization insulating layer 110. The first upper insulating layer 120 may be extended from the word line connection region WCR to the bit line connection region BCR.

The first word line contacts 111 may be formed to penetrate the first upper insulating layer 120 and the first planarization insulating layer 110 and may be connected to the first word lines WL1. The penetration contact plug 115 may be formed to penetrate the first upper insulating layer 120 and the first planarization insulating layer 110.

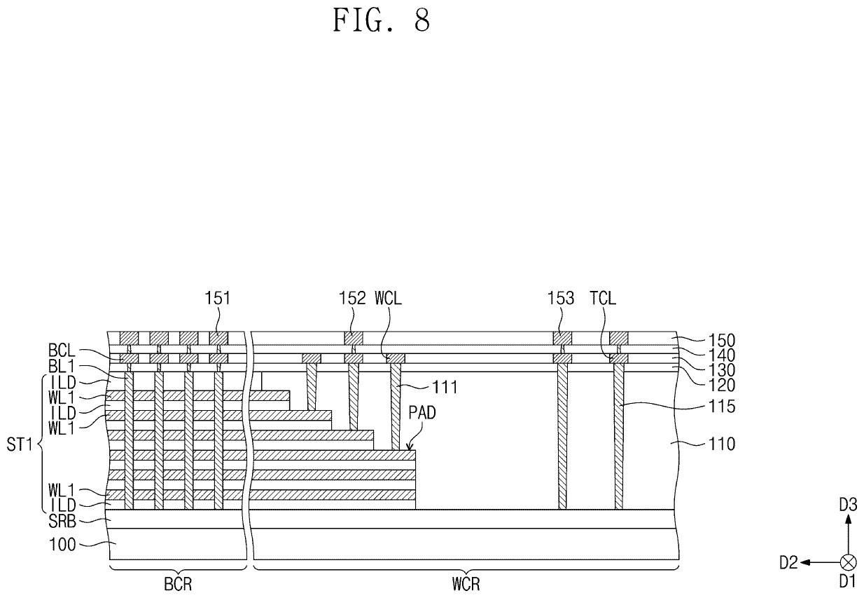

Referring to FIG. 8, the upper connection lines BCL, WCL, and TCL, upper interconnection lines, and the upper bonding pads 151, 152, and 153 may be formed on the first upper insulating layer 120. In addition, the first upper insulating layers 130, 140, and 150 may be additionally formed to cover the upper connection lines BCL, WCL, and TCL, the upper interconnection lines, and the upper bonding pads 151, 152, and 153.

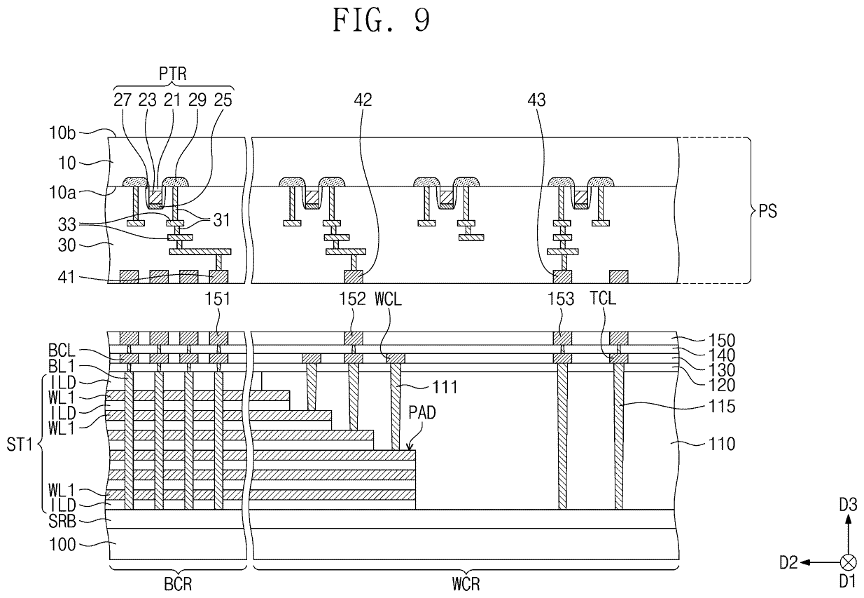

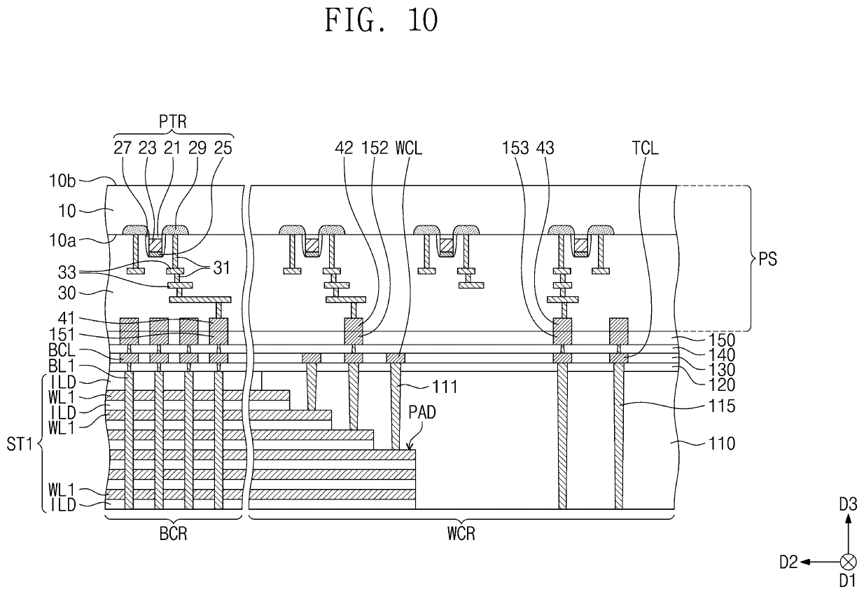

Referring to FIGS. 9 and 10, the peripheral circuit structure PS may be prepared. The peripheral circuit structure PS may include the same elements as those in the peripheral circuit structure PS described with reference to FIG. 3.

Next, the peripheral bonding pads 41, 42, and 43 of the peripheral circuit structure PS may be bonded to the upper bonding pads 151, 152, and 153, respectively.

The bonding process may include placing the peripheral bonding pads 41, 42, and 43 and the upper bonding pads 151, 152, and 153 to face each other and performing a thermo-compression process thereon. As a result of the thermo-compression process, a boundary between each pair of the peripheral bonding pads 41, 42, and 43 and the upper bonding pads 151, 152, and 153 may vanish. Thus, the peripheral bonding pads 41, 42, and 43 may be bonded to the upper bonding pads 151, 152, and 153, and the uppermost first upper insulating layer 150 on the first substrate 100 may be bonded to the first insulating layer 30 on the peripheral circuit structure PS.

After the bonding between the peripheral bonding pads 41, 42, and 43 and the upper bonding pads 151, 152, and 153, the first substrate 100 and the buffer layer SRB may be removed. The removal of the first substrate 100 and the buffer layer SRB may include sequentially performing a grinding process, a planarization process, a wet etching process, and a dry etching process.

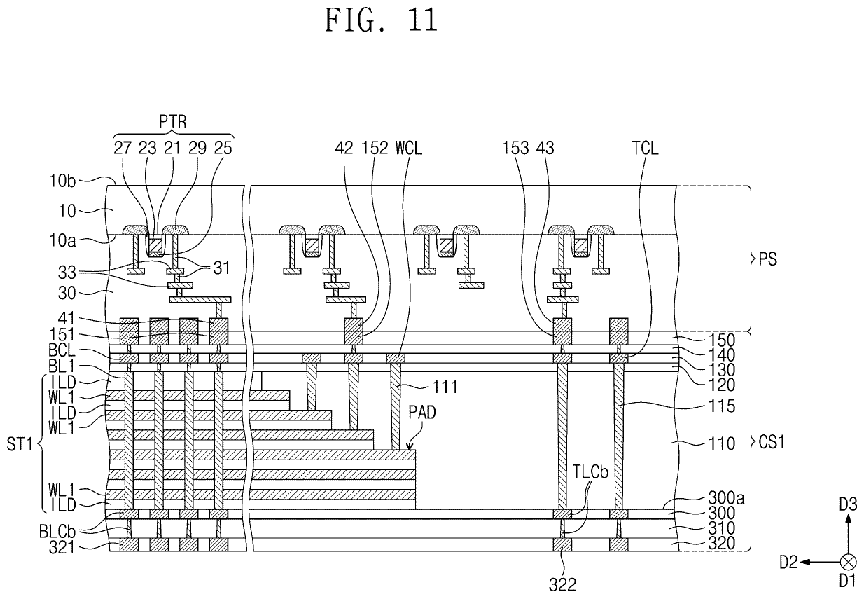

Referring to FIG. 11, the lower insulating layers 300, 310, and 320 may be formed on the first planarization insulating layer 110 and the first stack ST1, which are exposed after the removal of the first substrate 100 and the buffer layer SRB. In a process of forming the lower insulating layers 300, 310, and 320, the lower connection lines BCLb and TCLb, the lower interconnection lines, and the lower bonding pads 321 and 322, which are electrically connected to the first stack ST1, may also be formed. Thus, the first cell array structure CS1 described with reference to FIG. 3 may be formed.

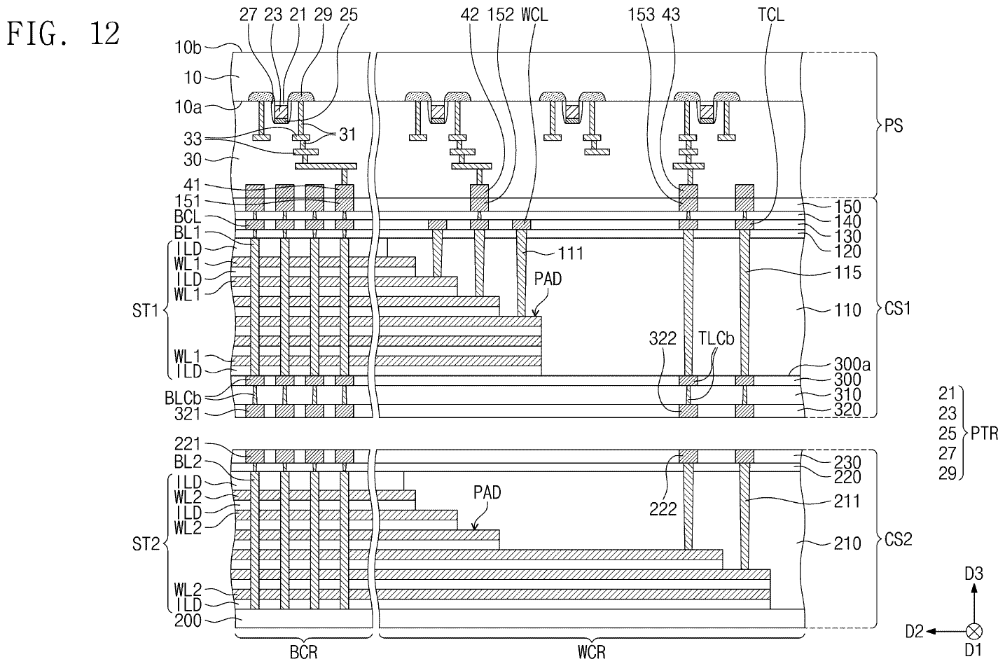

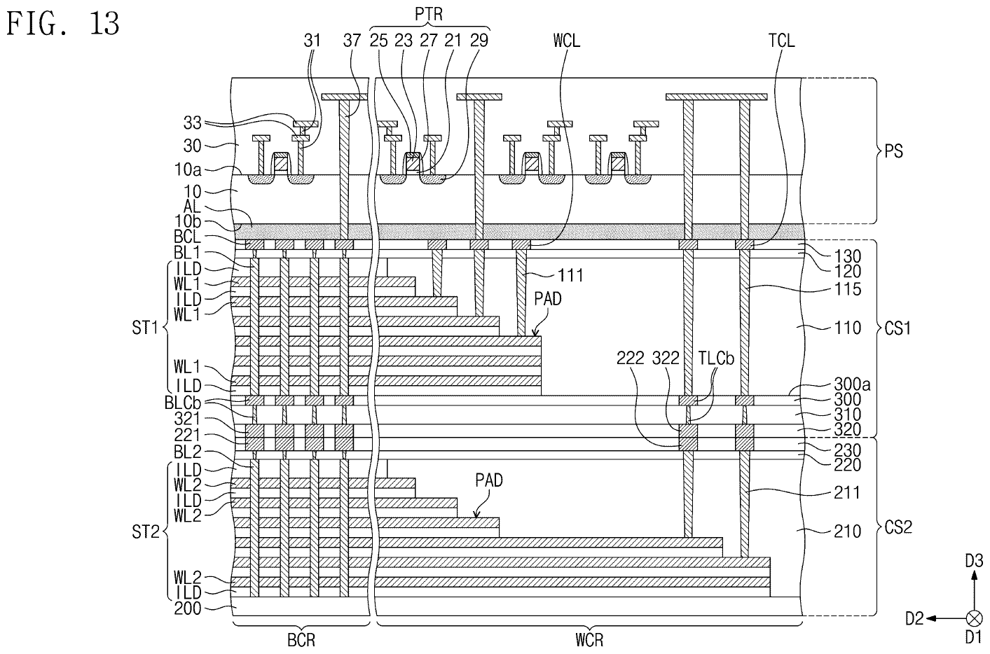

Referring to FIG. 12, the second cell array structure CS2 may be prepared. The second cell array structure CS2 may include the second stack ST2 and the second planarization insulating layer 210, which are provided on the second substrate 200. In an embodiment, the second cell array structure CS2 may be formed by substantially the same method as described with reference to FIGS. 6 to 8.

Referring back to FIG. 3, the lower bonding pads 321 and 322 of the first cell array structure CS1 may be bonded to the cell bonding pads 221 and 222 of the second cell array structure CS2. The bonding process may be substantially the same as that described with reference to FIGS. 9 and 10. A boundary between each pair of the lower bonding pads 321 and 322 and the cell bonding pads 221 and 222 may vanish, as a result of the bonding process. Thus, the lower bonding pads 321 and 322 may be bonded to the cell bonding pads 221 and 222, respectively, and the uppermost second upper insulating layer 230 on the second substrate 200 may be bonded to the lowermost lower insulating layer 320 of the first cell array structure CS1.

FIGS. 13 to 17 are sectional views illustrating three-dimensional semiconductor devices according to some embodiments of inventive concepts. For concise description, a previously described element may be identified by the same reference number without repeating an overlapping description thereof.

Referring to FIG. 13, an interface layer AL may be interposed between the first cell array structure CS1 and the peripheral circuit structure PS. The peripheral circuit structure PS may include the peripheral substrate 10, the first insulating layer 30, which is provided on the top surface 10a of the peripheral substrate 10, and peripheral penetration contacts 37, which are electrically connected to the peripheral circuit transistors PTR through the peripheral contact plugs 31 and the peripheral circuit interconnection lines 33. The peripheral penetration contacts 37 may be provided to penetrate the peripheral circuit structure PS and the interface layer AL and may be electrically connected to the upper connection lines BCL, WCL, and TCL of the first cell array structure CS1.

The interface layer AL may have a single- or multi-layered structure, which is formed of at least one of SiCN or silicon oxide. In an embodiment, the formation of the interface layer AL may include forming a first interface layer (not shown) on the first upper insulating layers 120 and 130 of the first cell array structure CS1 and forming a second interface layer (not shown) on the bottom surface 10b of the peripheral substrate 10. A plasma treatment step may be performed on the surfaces of the first and second interface layers to remove the —CN group at the ends of the SiCN layer and form dangling bonds. A deionized water treatment step may be performed on the surfaces of the first and second interface layers to form the —OH group on the dangling bond. The first and second interface layers may be placed to be in contact with each other, and then, a thermocompression process may be performed thereon. As a result of the thermocompression process, the —OH groups at interfaces between the first and second interface layers may combine to form H₂O, and the remaining —O— groups may combine with neighboring Si atoms to form a SiO₂ layer between the first and second interface layers. Accordingly, the peripheral circuit structure PS may be bonded to the first cell array structure CS1, and the interface layer AL may be formed between them. The interface layer AL may have a triple layer structure in which a SiCN layer, a SiO₂ layer, and a SiCN layer are sequentially stacked.

Although not shown, an insulating layer (not shown) may be interposed between side surfaces of the peripheral penetration contacts 37 and the peripheral substrate 10. Thus, the peripheral penetration contacts 37 may be electrically disconnected from the peripheral substrate 10. For example, the insulating layer (not shown) may be formed in the peripheral substrate 10 before the formation of the peripheral penetration contacts 37 penetrating the insulating layer, and in this case, it may be possible to reduce a failure rate and/or a process burden in a fabrication process, compared with a method of forming an insulating layer to fully cover the side surfaces of the peripheral penetration contacts 37.

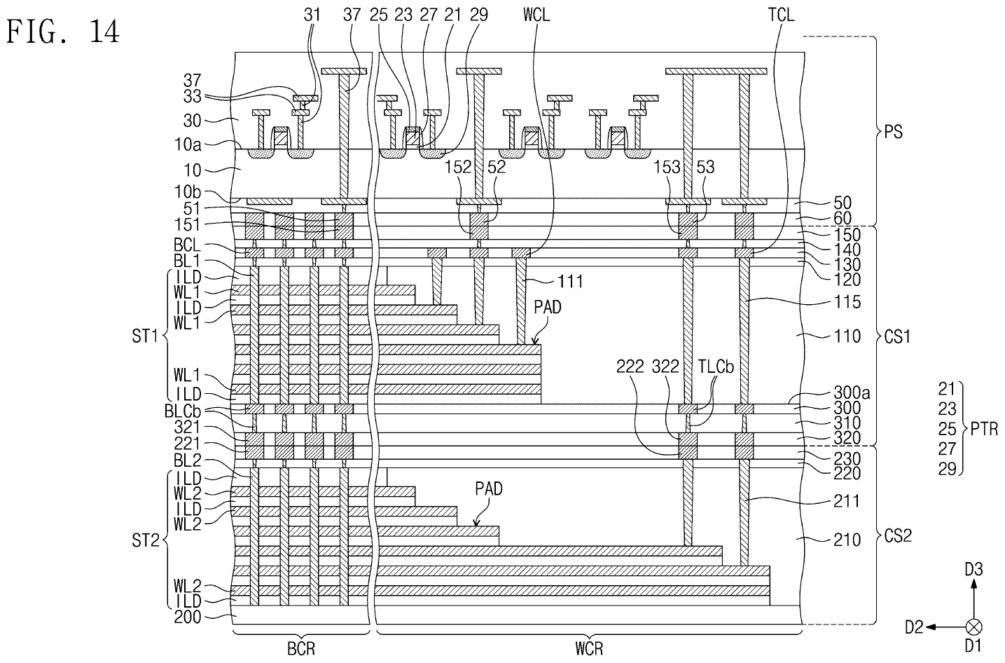

Referring to FIG. 14, the peripheral circuit structure PS may include the peripheral penetration contacts 37, which are electrically connected to the peripheral circuit transistors PTR through the peripheral contact plugs 31 and the peripheral circuit interconnection lines 33.

Second insulating layers 50 and 60 may be disposed on the bottom surface 10b of the peripheral substrate 10. The second insulating layers 50 and 60 may include a plurality of insulating layers. A plurality of lower circuit interconnection lines and a plurality of lower peripheral bonding pads 51, 52, and 53 may be provided in the second insulating layers 50 and 60. The lower peripheral bonding pads 51, 52, and 53 may be connected to the peripheral circuit transistors PTR through the lower circuit interconnection lines and the peripheral penetration contacts 37.

The lower peripheral bonding pads 51, 52, and 53 may be bonded to the upper bonding pads 151, 152, and 153 through a bonding process. In this case, the lowermost second insulating layer 60 of the peripheral circuit structure PS may be bonded to the uppermost first upper insulating layer 150 of the first cell array structure CS1.

The peripheral circuit transistors PTR of the peripheral circuit structure PS in the embodiment of FIG. 14 may be inverted, when compared with the embodiment of FIG. 3. In other words, the bonding process on the peripheral circuit structure PS may be performed in either a non-inverted or inverted manner, depending on the situation.

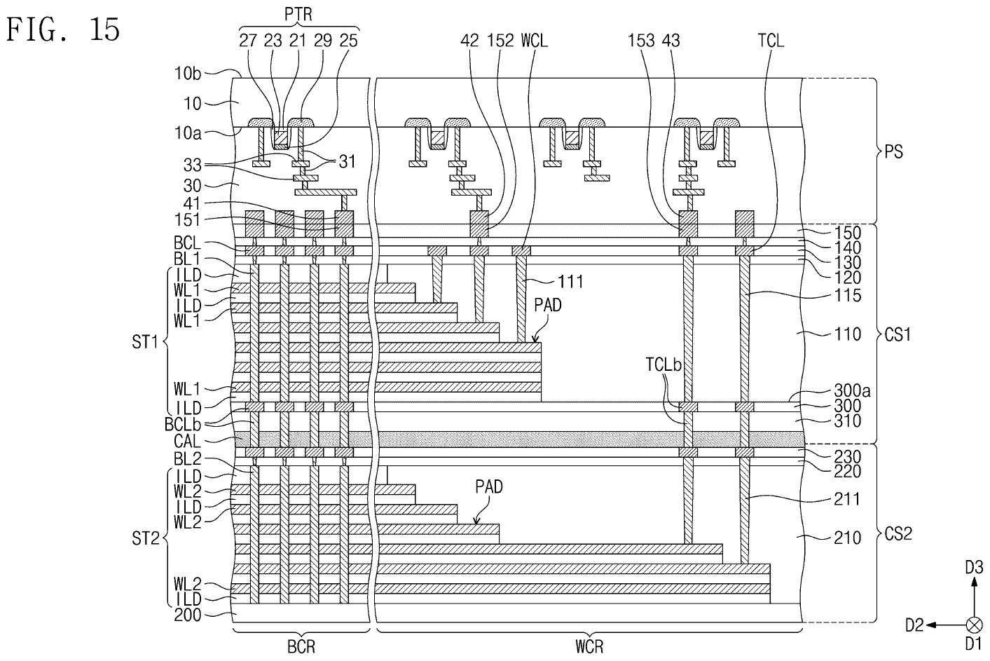

Referring to FIG. 15, a cell interface layer CAL may be interposed between the first and second cell array structures CS1 and CS2. The lower connection lines BCLb and TCLb of the first cell array structure CS1 may be provided to penetrate the lower insulating layer 300 and 310 and the cell interface layer CAL and may be electrically connected to the second cell array structure CS2.

The cell interface layer CAL may have a single- or multi-layered structure including at least one of SiCN or silicon oxide. The cell interface layer CAL may be formed by substantially the same process as that for the interface layer AL described with reference to FIG. 13.

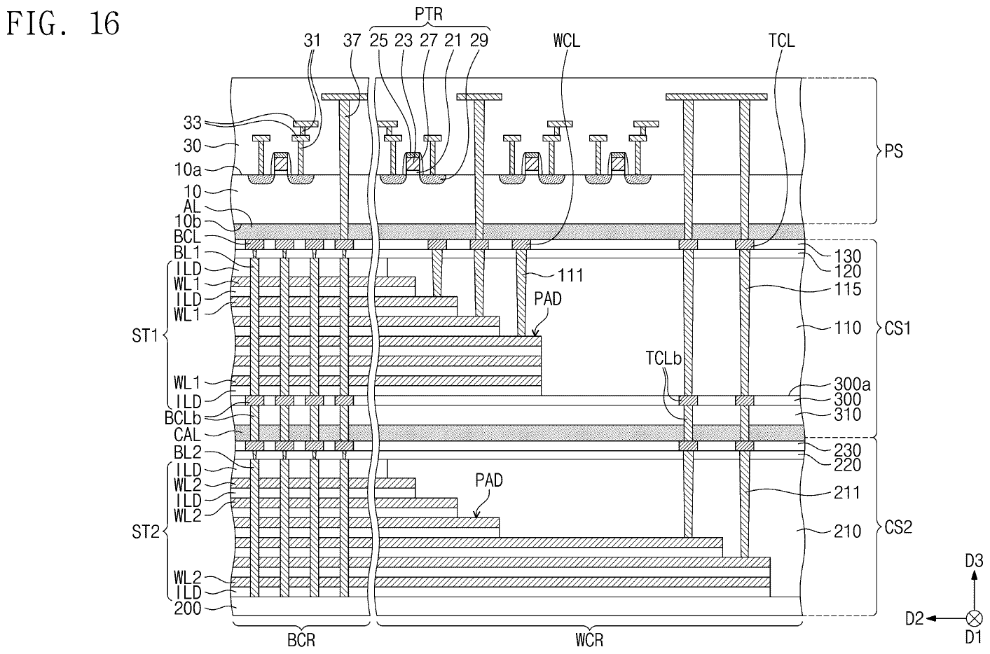

Referring to FIG. 16, the interface layer AL may be interposed between the first cell array structure CS1 and the peripheral circuit structure PS. The cell interface layer CAL may be interposed between the first and second cell array structures CS1 and CS2. The interface layer AL and the cell interface layer CAL may be formed through the same process as described with reference to FIGS. 13 and 15. In addition, the peripheral circuit structure PS, the first cell array structure CS1, and the second cell array structure CS2 may be electrically connected to each other in the same manner as described with reference to FIGS. 13 and 15.

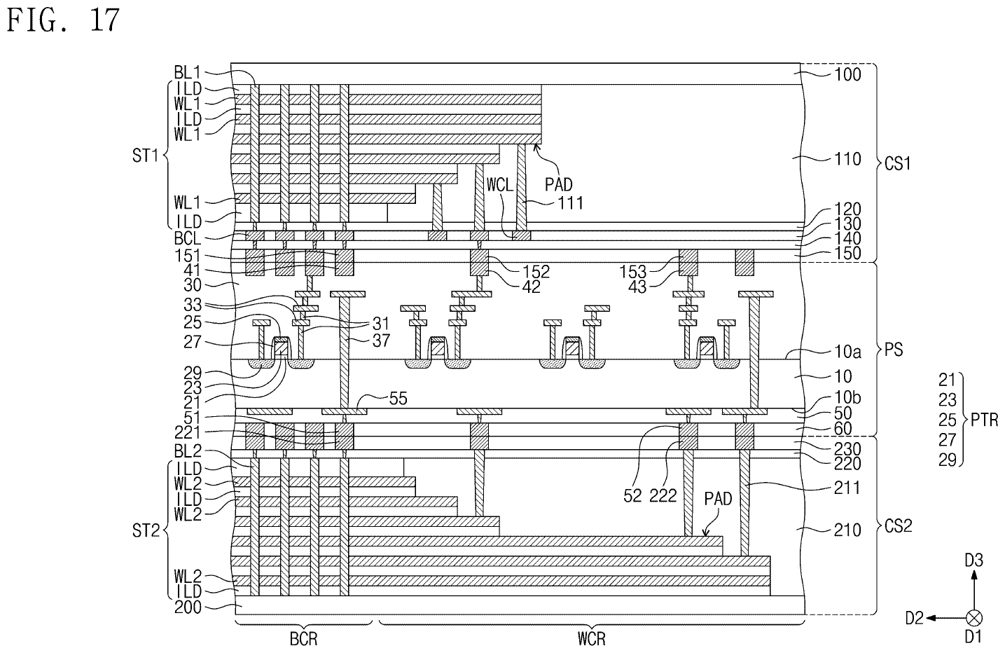

Referring to FIG. 17, the three-dimensional semiconductor device may include the first cell array structure CS1 on the peripheral circuit structure PS. The second cell array structure CS2 may be spaced apart from the first cell array structure CS1 with the peripheral circuit structure PS interposed therebetween. In other words, the peripheral circuit structure PS may be disposed on the second cell array structure CS2, and the first cell array structure CS1 may be disposed on the peripheral circuit structure PS.

The first and second cell array structures CS1 and CS2 may have the same features as those in the previous embodiment described with reference to FIG. 3. However, the first cell array structure CS1 may not include the penetration contact plug 115.

The peripheral circuit structure PS may include the peripheral substrate 10, the peripheral circuit transistors PTR and the peripheral contact plugs 31, which are provided on the peripheral substrate 10, the peripheral circuit interconnection lines 33, which are electrically connected to the peripheral circuit transistors PTR through the peripheral contact plugs 31, and the first insulating layer 30 enclosing them. The peripheral circuit structure PS may include the peripheral penetration contacts 37, which are electrically connected to the peripheral circuit transistors PTR through the peripheral contact plugs 31 and the peripheral circuit interconnection lines 33.

The peripheral bonding pads 41, 42, and 43, which are electrically connected to the peripheral circuit transistors PTR through the peripheral contact plugs 31 and the peripheral circuit interconnection lines 33, may be disposed in the first insulating layer 30.

The second insulating layers 50 and 60 may be disposed on the bottom surface 10b of the peripheral substrate 10. The second insulating layers 50 and 60 may include a plurality of insulating layers. A plurality of lower circuit interconnection lines and a plurality of lower peripheral bonding pads 51 and 52 may be provided in the second insulating layers 50 and 60. The lower peripheral bonding pads 51 and 52 may be connected to the peripheral circuit transistors PTR through the lower circuit interconnection lines 55 and the peripheral penetration contacts 37.

The upper bonding pads 151, 152, and 153 of the first cell array structure CS1 may be bonded to the peripheral bonding pads 41, 42, and 43 of the peripheral circuit structure PS through a bonding process. Here, the uppermost first upper insulating layer 150 of the first cell array structure CS1 may be bonded to the first insulating layer 30 of the peripheral circuit structure PS.

The lower peripheral bonding pads 51 and 52 of the peripheral circuit structure PS may be bonded to the cell bonding pads 221 and 222 of the second cell array structure CS2 through a bonding process. Here, the lowermost second insulating layer 60 of the peripheral circuit structure PS may be bonded to the uppermost second upper insulating layer 230 of the second cell array structure CS2.

According to an embodiment of inventive concepts, the generation extension may be achieved by a method of bonding cell structures to each other, not by a simple method of increasing the number of stacks. In other words, by connecting a first cell array structure to a second cell array structure using a bonding method, it may be possible to easily increase an integration density of the semiconductor device. This may make it possible to solve various issues, such as high process difficulty, long fabrication time, and high fabrication cost, in a simple stacking scheme.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While example embodiments of inventive concepts have been particularly shown and described, it will be understood by one of ordinary skill in the art that variations in form and detail may be made therein without departing from the spirit and scope of the attached claims.

What is claimed is:

1. A three-dimensional semiconductor device, comprising:
a first cell array structure;
a peripheral circuit structure on the first cell array structure; and
a second cell array structure spaced apart from the peripheral circuit structure with the first cell array structure therebetween,
wherein the first cell array structure comprises a lower insulating layer adjacent to the second cell array structure,
wherein each of the first cell array structure and the second cell array structure comprises
semiconductor patterns spaced apart from each other in a vertical direction perpendicular to a top surface of the lower insulating layer and extending in a first direction parallel to the top surface of the lower insulating layer,
word lines respectively enclosing the semiconductor patterns and extending in a second direction, which is parallel to the top surface of the lower insulating layer and is not parallel to the first direction, and
a bit line on first side surfaces of the semiconductor patterns and extending in the vertical direction.

2. The three-dimensional semiconductor device of claim 1, wherein
the first cell array structure comprises lower bonding pads in the lower insulating layer,
the second cell array structure comprises cell bonding pads, and
the lower bonding pads and the cell bonding pads are in contact with each other.

3. The three-dimensional semiconductor device of claim 2, wherein
the peripheral circuit structure comprises peripheral circuit transistors and peripheral bonding pads,
the peripheral bonding pads are connected to the peripheral circuit transistors,
the first cell array structure comprises an upper insulating layer and upper bonding pads,
the upper insulating layer is adjacent to the peripheral circuit structure,
the upper bonding pads are in the upper insulating layer, and
the upper bonding pads and the peripheral bonding pads are in contact with each other.

4. The three-dimensional semiconductor device of claim 2, further comprising:
an interface layer between the first cell array structure and the peripheral circuit structure,
wherein the peripheral circuit structure comprises peripheral circuit transistors and peripheral contact plugs, and
the peripheral contact plugs are connected to the peripheral circuit transistors,
wherein the first cell array structure comprises
a planarization insulating layer on the lower insulating layer and covering the word lines of the first cell array structure,
a penetration contact plug penetrating the planarization insulating layer,
a first upper connection line connected to the bit line of the first cell array structure,
a second upper connection line connected to one of the word lines of the first cell array structure, and
a third upper connection line connected to the penetration contact plug, and
the peripheral circuit structure further includes peripheral penetration contacts, and the peripheral penetration contacts penetrate the interface layer and are connected to the first upper connection line, the second upper connection line, and the third upper connection line, respectively.

5. The three-dimensional semiconductor device of claim 1, further comprising:
a data storage pattern on second side surfaces of the semiconductor patterns, wherein
the second side surfaces of the semiconductor patterns are opposite the first side surfaces of the semiconductor patterns in the first direction.

6. The three-dimensional semiconductor device of claim 5, wherein
the data storage pattern comprises a storage electrode, a plate electrode, and a capacitor dielectric layer between the storage electrode and the plate electrode.

7. The three-dimensional semiconductor device of claim 1, further comprising:
a gate insulating layers surrounding each of the semiconductor patterns, respectively, wherein
each one of the gate insulating layers is between a corresponding one of the semiconductor patterns and a corresponding one of the word lines.

8. The three-dimensional semiconductor device of claim 1, further comprising:
a cell interface layer between the first cell array structure and the second cell array structure,
wherein the first cell array structure comprises
a planarization insulating layer on the lower insulating layer and covering the word lines of the first cell array structure,
a penetration contact plug penetrating the planarization insulating layer, and
a first lower connection line in the lower insulating layer and connected to the bit line of the first cell array structure, and
a second lower connection line in the lower insulating layer and connected to the penetration contact plug,
wherein the first lower connection line and the second lower connection line penetrate the cell interface layer and are connected to the bit line of the second cell array structure and the word lines of the second cell array structure, respectively.

9. The three-dimensional semiconductor device of claim 8, wherein
the peripheral circuit structure comprises peripheral circuit transistors and peripheral bonding pads connected to the peripheral circuit transistors,
the first cell array structure comprises an upper insulating layer and upper bonding pads,
the upper insulating layer is adjacent to the peripheral circuit structure,
the upper bonding pads are in the upper insulating layer, and
the upper bonding pads and the peripheral bonding pads are in contact with each other.

10. The three-dimensional semiconductor device of claim 8, further comprising:
an interface layer between the first cell array structure and the peripheral circuit structure,
wherein the peripheral circuit structure comprises peripheral circuit transistors and peripheral contact plugs connected to the peripheral circuit transistors,
wherein the first cell array structure comprises
a first upper connection line connected to the bit line of the first cell array structure,
a second upper connection line connected to one of the word lines of the first cell array structure,
a third upper connection line connected to the penetration contact plug, and
an upper insulating layer covering the first upper connection line, the second upper connection line, and the third upper connection line,
wherein the interface layer is between the upper insulating layer of the first cell array structure and the peripheral circuit structure, and
the peripheral circuit structure further includes peripheral penetration contacts, and the peripheral penetration contacts penetrate the interface layer and are connected to the first upper connection line, the second upper connection line, and the third upper connection line, respectively.

11. A three-dimensional semiconductor device, comprising:
a first cell array structure;
a peripheral circuit structure on the first cell array structure; and
a second cell array structure spaced apart from the peripheral circuit structure with the first cell array structure therebetween,
wherein the first cell array structure comprises a lower insulating layer, which is adjacent to the second cell array structure, and lower bonding pads in the lower insulating layer,
the second cell array structure comprises cell bonding pads in contact with corresponding ones of the lower bonding pads,
wherein each of the first cell array structure and the second cell array structure comprises
a bit line connection region and a word line connection region,
semiconductor patterns on the bit line connection region, the semiconductor patterns being spaced apart from each other in a vertical direction and extending in a first direction, the vertical direction being perpendicular to a top surface of the lower insulating layer, and the first direction parallel to the top surface of the lower insulating layer,
word lines respectively enclosing the semiconductor patterns and extending in a second direction to a region on the word line connection region, the second direction being parallel to the top surface of the lower insulating layer and not being parallel to the first direction, and
a bit line on the bit line connection region and extending in the vertical direction, the bit line being on first side surfaces of the semiconductor patterns.

12. The three-dimensional semiconductor device of claim 11,
wherein the first cell array structure comprises
a planarization insulating layer on the lower insulating layer and covering the word lines of the first cell array structure, and
a penetration contact plug penetrating the planarization insulating layer,
wherein the lower bonding pads comprises a first lower bonding pad and a second lower bonding pad,
the first lower bonding pad is in the bit line connection region and connected to the bit line of the first cell array structure,
the second lower bonding pad is in the word line connection region and connected to the penetration contact plug,
the cell bonding pads comprises a first cell bonding pad and a second cell bonding pad,
the first cell bonding pad is in the bit line connection region and connected to the bit line of the second cell array structure,
the second cell bonding pad is in the word line connection region and connected to one of the word lines of the second cell array structure.

13. The three-dimensional semiconductor device of claim 12, wherein
the first lower bonding pad and the first cell bonding pad are in contact with each other, and
the second lower bonding pad and the second cell bonding pad are in contact with each other.

14. The three-dimensional semiconductor device of claim 12,
wherein the peripheral circuit structure comprises peripheral circuit transistors, a first peripheral bonding pad, a second peripheral bonding pad, and a third peripheral bonding pad,
wherein the first peripheral bonding pad, the second peripheral bonding pad, and the third peripheral bonding pad are connected to the peripheral circuit transistors,
wherein the first cell array structure comprises an upper insulating layer on the planarization insulating layer and upper bonding pads in the upper insulating layer,
wherein the upper bonding pads comprise a first upper bonding pad in the bit line connection region, a second upper bonding pad in the word line connection region, and a third upper bonding pad in the word line connection region,
the first upper bonding pad is connected to the bit line of the first cell array structure,
the second upper bonding pad is connected to one of the word lines of the first cell array structure,
the third upper bonding pad is connected to the penetration contact plug, and
the first upper bonding pad, the second upper bonding pad, and the third upper bonding pad are in contact with the first peripheral bonding pad, the second peripheral bonding pad, and the third peripheral bonding pad, respectively.

15. The three-dimensional semiconductor device of claim 12, further comprising:
an interface layer between the first cell array structure and the peripheral circuit structure,
wherein the peripheral circuit structure comprises peripheral circuit transistors and peripheral contact plugs connected to the peripheral circuit transistors,
wherein the first cell array structure comprises a first upper connection line in the bit line connection region, a second upper connection line in the word line connection region, and a third upper connection line in the word line connection region, and an upper insulating layer covering the first upper connection line, the second upper connection line, and the third upper connection line,
the first upper connection line is connected to the bit line of the first cell array structure,
the second upper connection line is connected to one of the word lines of the first cell array structure, and
the third upper connection line is connected to the penetration contact plug, wherein the interface layer is between the upper insulating layer of the first cell array structure and the peripheral circuit structure, and
wherein the peripheral circuit structure further includes peripheral penetration contacts, and the peripheral penetration contacts penetrate the interface layer and are connected to the first upper connection line, the second upper connection line, and the third upper connection line, respectively.

16. The three-dimensional semiconductor device of claim 11, further comprising:
a data storage pattern on second side surfaces of the semiconductor patterns, wherein
further comprise second side surfaces,
the second side surfaces of the semiconductor patterns are opposite the first side surfaces of the semiconductor patterns in the first direction.

17. The three-dimensional semiconductor device of claim 16, wherein the data storage pattern comprises a storage electrode, a plate electrode, and a capacitor dielectric layer between the storage electrode and the plate electrode.

18. A three-dimensional semiconductor device, comprising:
a first cell array structure;
a peripheral circuit structure on the first cell array structure; and
a second cell array structure spaced apart from the peripheral circuit structure with the first cell array structure therebetween,
wherein the peripheral circuit structure comprises peripheral circuit transistors and peripheral bonding pads,
the peripheral bonding pads are connected to the peripheral circuit transistors,
the first cell array structure comprises upper bonding pads in contact with corresponding ones of the peripheral bonding pads,
the first cell array structure comprises a lower insulating layer adjacent to the second cell array structure,
wherein each of the first cell array structure and the second cell array structure comprises
a bit line connection region and a word line connection region,
semiconductor patterns on the bit line connection region, the semiconductor patterns being spaced apart from each other in a vertical direction and extending in a first direction, the vertical direction being perpendicular to a top surface of the lower insulating layer, and the first direction being parallel to the top surface of the lower insulating layer,
word lines respectively enclosing the semiconductor patterns and extending in a second direction to a region on the word line connection region, the second direction being parallel to the top surface of the lower insulating layer and not being parallel to the first direction, and
a bit line on the bit line connection region and extending in the vertical direction, the bit line being on first side surfaces of the semiconductor patterns.

19. The three-dimensional semiconductor device of claim 18,
wherein the first cell array structure comprises
a first planarization insulating layer on the lower insulating layer and covering the word lines of the first cell array structure and a penetration contact plug penetrating the first planarization insulating layer,
wherein the upper bonding pads comprise a first upper bonding pad connected to the bit line of the first cell array structure in the bit line connection region, a second upper bonding pad connected to one the word lines of the first cell array structure in the bit line connection region, and a third upper bonding pad connected to the penetration contact plug in the word line connection region,
wherein the peripheral bonding pads comprise a first peripheral bonding pad, a second peripheral bonding pad, and a third peripheral bonding pad, and
the first upper bonding pad, the second upper bonding pad, and the third upper bonding pad are in contact with the first peripheral bonding pad, the second peripheral bonding pad, and the third peripheral bonding pad, respectively.

20. The three-dimensional semiconductor device of claim 19, wherein
the first cell array structure comprises lower bonding pads in the lower insulating layer,
the lower bonding pads comprise a first lower bonding pad and a second lower bonding pad,
the first lower bonding pad is connected to the bit line of the first cell array structure in the bit line connection region,
the second lower bonding pad is connected to the penetration contact plug in the word line connection region,
the second cell array structure comprises a first cell bonding pad and a second cell bonding pad,
the first cell bonding pad is connected to the bit line of the second cell array structure in the bit line connection region,
the second cell bonding pad is connected to one of the word lines of the second cell array structure in the word line connection region,
the first lower bonding pad and the first cell bonding pad are in contact with each other, and
the second lower bonding pad and the second cell bonding pad are in contact with each other.
